(19) United States
(12) Patent Application Publication
(10) Pub. No.: US 2025/0300107 A1
(43) Pub. Date: Sep. 25, 2025

(54) SEMICONDUCTOR DEVICE AND MANUFACTURING METHOD THEREOF

(71) Applicant: FUJI ELECTRIC CO., LTD., Kawasaki-shi (JP)

(72) Inventors: Yoshinori OTOMO, Matsumoto-city (JP); Shogo MIZUNO, Matsumoto-city (JP); Yoko NAKAMURA, Matsumoto-city (JP)

(73) Assignee: FUJI ELECTRIC CO., LTD., Kawasaki-shi (JP)

(21) Appl. No.: 19/064,407

(22) Filed: Feb. 26, 2025

(30) Foreign Application Priority Data
Mar. 22, 2024 (JP) 2024-046526

(51) Int. Cl. H01L 23/00; H01L 21/48; H01L 21/56; H01L 23/367; H01L 23/498; H01L 25/07; H10D 80/20

(52) U.S. Cl. CPC H01L 24/05; H01L 24/80; H01L 21/4853; H01L 21/4875; H01L 21/56; H01L 23/3672; H01L 23/49811; H01L 23/49838; H01L 24/29; H01L 24/32; H01L 24/45; H01L 24/48; H01L 24/49; H01L 24/73; H01L 24/83; H01L 25/072; H01L 2224/05541; H01L 2224/05553; H01L 2224/05557; H01L 2224/05559; H01L 2224/29109; H01L 2224/29111; H01L 2224/29113; H01L 2224/29118; H01L 2224/2912; H01L 2224/29139; H01L 2224/29147; H01L 2224/32227; H01L 2224/32238; H01L 2224/32245; H01L 2224/45124; H01L 2224/45144; H01L 2224/45147; H01L 2224/48247; H01L 2224/49175; H01L 2224/73215; H01L 2224/73265; H01L 2224/80201; H01L 2224/83205; H01L 2924/3512; H10D 80/251

(57) ABSTRACT

A semiconductor device includes a conductive plate, and a terminal including a bonding portion having a rectangular plate shape in a plan view and having a bottom surface bonded to the conductive plate and a top surface having an indentation area with indentations, and a ramp portion integrally connected to the bonding portion at a rear end thereof and extending from the bonding portion upward in a direction away from the top surface. The indentation area includes a plurality of sub-indentation areas each having a thickness from the bottom surface in a thickness direction orthogonal to the bottom surface is less than a thickness of the bonding portion from the bottom surface to the top surface at an area other than the indentation area.

### CROSS-REFERENCE TO RELATED APPLICATION

This application is based upon and claims the benefit of priority of the prior Japanese Patent Application No. 2024-046526, filed on Mar. 22, 2024, the entire contents of which are incorporated herein by reference.

### BACKGROUND OF THE INVENTION

### 1. Field of the Invention

The present embodiments relate to a semiconductor device and a manufacturing method thereof.

### 2. Background of the Related Art

In a semiconductor device, a terminal is bonded to a wiring plate by ultrasonic bonding (for example, see Japanese Laid-open Patent Publication No. 2022-189515 and Japanese Laid-open Patent Publication No. 2015-056412). In addition, a wire is bonded to an electrode on a front surface of a semiconductor element by ultrasonic bonding (for example, see Japanese Laid-open Patent Publication No. 2012-124247).

### SUMMARY OF THE INVENTION

In one aspect of the present embodiment, there is provided a semiconductor device including: a conductive plate; and a terminal including a bonding portion having a rectangular plate shape in a plan view of the semiconductor device and having a bottom surface bonded to the conductive plate and a top surface having an indentation area with indentations, the bonding portion having a rear end and a front end opposite to each other, and a ramp portion integrally connected to the bonding portion at the rear end thereof and extending from the bonding portion upward in a direction away from the top surface, wherein the indentation area includes a plurality of sub-indentation areas, each having a thickness, from the bottom surface in a thickness direction orthogonal to the bottom surface, that is less than a thickness of the bonding portion from the bottom surface to the top surface at an area of the bonding portion other than the indentation area.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a side view of the semiconductor device according to the first embodiment;

FIG. 3 is a plan view of a semiconductor unit included in the semiconductor device according to the first embodiment;

FIG. 4 is a sectional view of the semiconductor unit included in the semiconductor device according to the first embodiment;

FIG. 5 is a plan view of a connection terminal bonded to a conductive circuit pattern included in the semiconductor device according to the first embodiment;

FIG. 6 is a sectional view of the connection terminal bonded to the conductive circuit pattern included in the semiconductor device according to the first embodiment;

FIG. 7 is a flowchart illustrating a semiconductor device manufacturing method according to the first embodiment;

FIG. 8 is a plan view of a main portion after an assembly step in the semiconductor device manufacturing method according to the first embodiment;

FIG. 9 is a plan view of a connection terminal disposed on a conductive circuit pattern after the assembly step in the semiconductor device manufacturing method according to the first embodiment;

FIG. 10 is a sectional view of the connection terminal disposed on the conductive circuit pattern after the assembly step in the semiconductor device manufacturing method according to the first embodiment;

FIG. 11 is a side view of a bonding tool used in a wiring step in the semiconductor device manufacturing method according to the first embodiment;

FIG. 12 illustrates a bonding step included in the wiring step in the semiconductor device manufacturing method according to the first embodiment;

FIG. 13 illustrates an additional bonding step included in the wiring step in the semiconductor device manufacturing method according to the first embodiment;

FIG. 14 is a plan view of a connection terminal bonded to a conductive circuit pattern included in a semiconductor device according to a reference example 1;

FIG. 15 is a sectional view of the connection terminal bonded to the conductive circuit pattern included in the semiconductor device according to the reference example 1;

FIG. 16 is a plan view of a connection terminal bonded to a conductive circuit pattern included in a semiconductor device according to a second embodiment;

FIG. 17 is a sectional view of the connection terminal bonded to the conductive circuit pattern included in the semiconductor device according to the second embodiment;

FIG. 18 is a sectional view of a connection terminal bonded to a conductive circuit pattern included in a semiconductor device according to a reference example 2;

FIG. 19 is a plan view of a connection terminal bonded to a conductive circuit pattern included in a semiconductor device according to a third embodiment;

FIG. 20 is a sectional view of the connection terminal bonded to the conductive circuit pattern included in the semiconductor device according to the third embodiment;

FIG. 21 is a plan view of a connection terminal bonded to a conductive circuit pattern included in a semiconductor device according to a fourth embodiment;

FIG. 22 is a sectional view of the connection terminal bonded to the conductive circuit pattern included in the semiconductor device according to the fourth embodiment; and

FIG. 23 is a plan view of a connection terminal bonded to a conductive circuit pattern included in a semiconductor device according to a fifth embodiment.

### DETAILED DESCRIPTION OF THE INVENTION

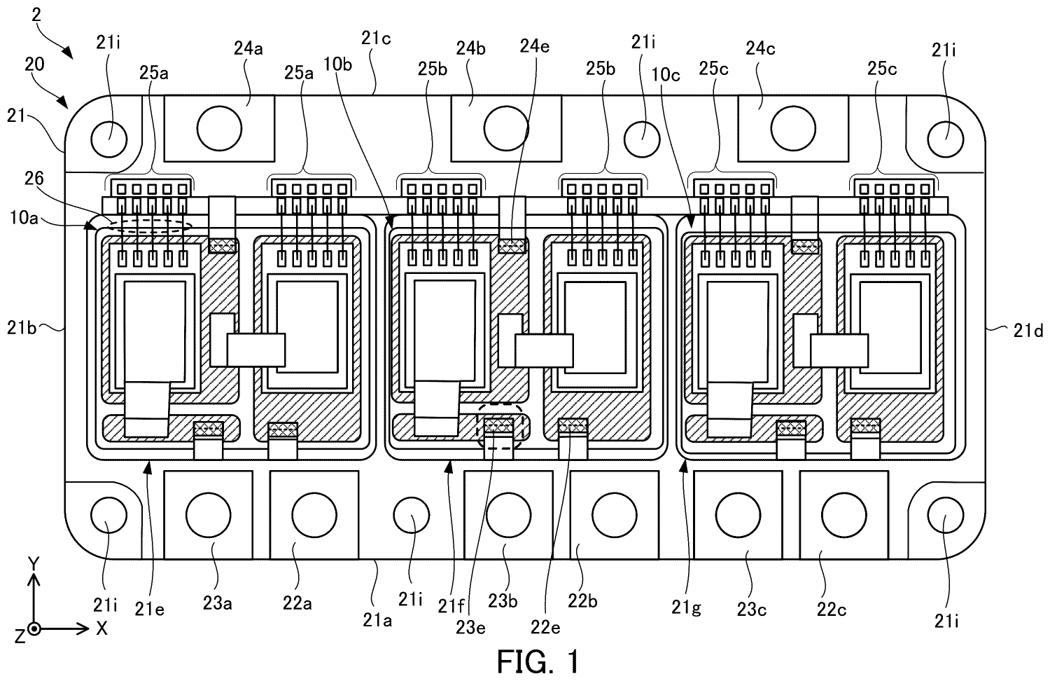

Hereinafter, embodiments will be described with reference to the accompanying drawings. In the following description, regarding a semiconductor device 1 in FIG. 1, terms “front surface” and “top surface” each express an X-Y surface facing upward (the +Z direction). Likewise, regarding the semiconductor device 1 in FIG. 1, a term “up” expresses the upper direction (the +Z direction). Regarding the semiconductor device 1 in FIG. 1, terms “rear surface” and “bottom surface” each express an X-Y surface facing downward (the −Z direction). Likewise, regarding the semiconductor device 1 in FIG. 1, a term “down” expresses the lower direction (the −Z direction). In all the other drawings, the above terms also mean their respective directions as appropriate. Regarding the semiconductor device 1 in FIG. 1, terms “higher level” and “upper level” express an upper location (in the +Z direction). Likewise, regarding the semiconductor device 1 in FIG. 1, a term “lower level” expresses a lower location (in the −Z direction). The terms “front surface”, “top surface”, “up”, “rear surface”, “bottom surface”, “down”, and “side surface” are simply used as convenient expressions to determine relative positional relationships and do not limit the technical ideas of the embodiments. For example, the terms “up” and “down” may mean directions other than the vertical directions with respect to the ground. That is, the directions expressed by “up” and “down” are not limited to the directions relating to the gravitational force. In addition, in the following description, when a component contained in a material represents 80 vol % or more of the material, this component will be referred to as “main component” of the material. In addition, an expression “approximately the same” may be used when an error between two elements is within ±10%. In addition, even when two elements are not exactly perpendicular, orthogonal, or parallel to each other, the two elements may be described as being “perpendicular”, “orthogonal”, or “parallel” to each other if the error is within ±10°.

### First Embodiment

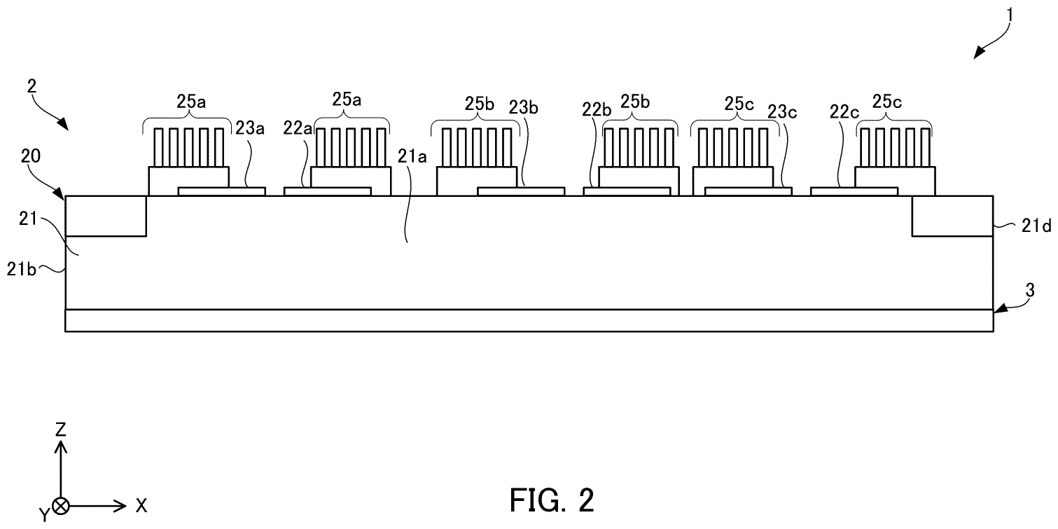

A semiconductor device 1 according to a first embodiment will be described with reference to FIGS. 1 and 2. FIG. 1 is a plan view of a semiconductor device according to a first embodiment, and FIG. 2 is a side view of the semiconductor device according to the first embodiment. Specifically, FIG. 2 is a side view in which a side portion of the semiconductor device 1 in FIG. 1, the side portion being parallel to the X-Z plane, is seen in the +Y direction.

The semiconductor device 1 includes a semiconductor module 2 and a heat dissipation plate 3. The semiconductor module 2 includes semiconductor units 10a, 10b, and 10c, and a case 20 storing the semiconductor units 10a, 10b, and 10c. The semiconductor units 10a, 10b, and 10c stored in the case 20 are sealed by a sealing material (not illustrated). Each of the semiconductor units 10a, 10b, and 10c has the same construction. When the semiconductor units 10a, 10b, and 10c are not distinguished from each other, any one of the semiconductor units 10a, 10b, and 10c will be described as a semiconductor unit 10. These semiconductor units 10 will be described in detail below.

The case 20 included in the semiconductor module 2 includes: an outer frame 21; first connection terminals 22a, 22b, and 22c; second connection terminals 23a, 23b, and 23c; a W-phase output terminal 24a, a V-phase output terminal 24b, and a U-phase output terminal 24c; and control terminals 25a, 25b, and 25c.

The outer frame 21 has an approximately rectangular shape in plan view, and four sides of the outer frame 21 constitute outer walls 21a, 21b, 21c, and 21d. The outer walls 21a and 21c constitute the long sides of the outer frame 21, and the outer walls 21b and 21d constitute the short sides of the outer frame 21. In addition, the outer frame 21 has corner portions, each of which is formed by connection of two of the outer walls 21a, 21b, 21c, and 21d. These corner portions may be right-angled corner portions or rounded corner portions as illustrated in FIG. 1. Fastening holes 21i extending through the outer frame 21 are formed in their respective corner portions, etc., of the front surface of the outer frame 21. Each of the fastening holes 2li in the corner portions, etc., of the outer frame 21 may be formed in a surface lower than the front surface of the outer frame 21.

In the front surface of the outer frame 21, unit storage spaces 21e, 21f, and 21g are defined along the outer walls 21a and 21c. Each of these unit storage spaces 21e, 21f, and 21g has a rectangular shape in plan view. The semiconductor units 10a, 10b, and 10c are stored in the unit storage spaces 21e, 21f, and 21g, respectively. The outer frame 21 is attached to the front surface of the heat dissipation plate 3 on which the semiconductor units 10a, 10b, and 10c have been arranged in the X direction. After the outer frame 21 is attached to the heat dissipation plate 3, the unit storage spaces 21e, 21f, and 21g of the outer frame 21 enclose (store) their respective semiconductor units 10a, 10b, and 10c arranged on the heat dissipation plate 3.

The outer frame 21 has the first connection terminals 22a, 22b, and 22c and the second connection terminals 23a, 23b, and 23c on its front surface near the outer wall 21a in plan view. The first and second connection terminals 22a and 23a, 22b and 23b, and 22c and 23c are formed at the unit storage spaces 21e, 21f, and 21g, respectively. The first connection terminals 22a, 22b, and 22c and the second connection terminals 23a, 23b, and 23c each have one end portion that is exposed to the outside on the front surface near the outer wall 21a. In addition, the first connection terminals 22a, 22b, and 22c and the second connection terminals 23a, 23b, and 23c each have the other end portion that is exposed to the outside in a corresponding one of the unit storage spaces 21e, 21f, and 21g. Each of the other end portions is electrically connected to a corresponding one of the semiconductor units 10a, 10b, and 10c.

For example, in the unit storage space 21f, first and second bonding portions 22e and 23e (bonding portions), which are the other end portions of the first and second connection terminals 22b and 23b, are bonded to the semiconductor unit 10b (to conductive circuit patterns 11b1 and 11b3, which are included in the semiconductor unit 10b and which will be described below) by ultrasonic bonding. The other first and second bonding portions (reference characters thereof are omitted), which are the other end portions of the first and second connection terminals 22a and 23a and the first and second connection terminals 22c and 23c, are also bonded to the semiconductor unit 10a and the semiconductor unit 10c (to conductive circuit patterns 11b1 and 11b3, which are included in the semiconductor units 10a and 10c and which will be described below) by ultrasonic bonding.

The W-phase output terminal 24a, the V-phase output terminal 24b, and the U-phase output terminal 24c are formed on the front surface near the outer wall 21c. The W-phase output terminal 24a, the V-phase output terminal 24b, and the U-phase output terminal 24c are formed at the unit storage spaces 21e, 21f, and 21g, respectively. The W-phase output terminal 24a, the V-phase output terminal 24b, and the U-phase output terminal 24c each have one end portion that is exposed to the outside on the front surface near the outer wall 21c. The W-phase output terminal 24a, the V-phase output terminal 24b, and the U-phase output terminal 24c each have the other end portion that is exposed to the outside in a corresponding one of the unit storage spaces 21e, 21f, and 21g and that is electrically connected to a corresponding one of the semiconductor units 10a, 10b, and 10c.

For example, in the unit storage space 21f, a third bonding portion 24e, which is the other end portion of the V-phase output terminal 24b, is bonded to the semiconductor unit 10b (a conductive circuit pattern 11b2, which is included in the semiconductor unit 10b and which will be described below) by ultrasonic bonding. The other third bonding portions (reference characters thereof are omitted), which are the other end portions of the W-phase output terminal 24a and the U-phase output terminal 24c, are also bonded to their respective semiconductor units 10a and 10c (to conductive circuit patterns 11b2, which are included in their respective semiconductor units 10a and 10c and which will be described below) by ultrasonic bonding.

In addition, the outer frame 21 has openings in the front surface near the outer wall 21a, and the openings are formed where the one end portions of the first connection terminals 22a, 22b, and 22c and the second connection terminals 23a, 23b, and 23c are located. Nuts are stored to face their respective openings. The outer frame 21 also has openings in the front surface near the outer wall 21c, and the openings are formed where the one end portions of the U-phase output terminal 24c, the V-phase output terminal 24b, and the W-phase output terminal 24a are located. Nuts are stored to face their respective openings.

In addition, the outer frame 21 includes the control terminals 25a, 25b, and 25c. The control terminals 25a are arranged on the front surface near the +Y direction side of the unit storage space 21e in plan view (the side being located in the direction of the outer wall 21c). In the same way, the control terminals 25b and 25c are also arranged on the front surface near the +Y direction side of the unit storage spaces 21f and 21g in plan view (the side being located in the direction of the outer wall 21c). The control terminals 25a are divided into two groups, and the same applies to the control terminals 25b and 25c. Each of the control terminals 25a, 25b, and 25c is formed in the shape of the letter “J” (or “U”), and has one end portion extending vertically upward (in the +Z direction) from the front surface near the outer wall 21c of the outer frame 21. The control terminals 25a, 25b, and 25c each have the other end portion that faces in the −Y direction from the +Y direction side (the side being located in the direction of the outer wall 21c) of a corresponding one of the unit storage spaces 21e, 21f, and 21g. These other end portions are exposed to the outside in their respective unit storage spaces 21e, 21f, and 21g.

The outer frame 21 includes the first connection terminals 22a, 22b, and 22c, the second connection terminals 23a, 23b, and 23c, the W-phase output terminal 24a, the V-phase output terminal 24b, the U-phase output terminal 24c, and the control terminals 25a, 25b, and 25c, each of which is integrally formed by injection molding using thermoplastic resin. In this way, the case 20 is constructed. Examples of the thermoplastic resin include polyphenylene sulfide resin, polybutylene terephthalate resin, polybutylene succinate resin, polyamide resin, and acrylonitrile butadiene styrene resin.

In addition, the first connection terminals 22a, 22b, and 22c, the second connection terminals 23a, 23b, and 23c, the W-phase output terminal 24a, the V-phase output terminal 24b, the U-phase output terminal 24c, and the control terminals 25a, 25b, and 25c are each made of a metal material having an excellent electrical conductivity. For example, this metal material is copper, aluminum, or an alloy containing at least one of these kinds of elements as its main component. The surface of each of the first connection terminals 22a, 22b, and 22c, the second connection terminals 23a, 23b, and 23c, the W-phase output terminal 24a, the V-phase output terminal 24b, the U-phase output terminal 24c, and the control terminals 25a, 25b, and 25c may be plated. The material used for this plating is, for example, nickel, a nickel-phosphorus alloy, or a nickel-boron alloy.

Sealing material is injected into the unit storage spaces 21e, 21f, and 21g of the outer frame 21, so as to seal the semiconductor units 10 inside the unit storage spaces 21e, 21f, and 21g. The sealing material seals the other end of each of the first connection terminals 22a, 22b, and 22c, the second connection terminals 23a, 23b, and 23c, the W-phase output terminal 24a, the V-phase output terminal 24b, the U-phase output terminal 24c, and the control terminals 25a, 25b, and 25c in the unit storage spaces 21e, 21f, and 21g. The sealing material may be thermosetting resin. The thermosetting resin is, for example, epoxy resin, phenol resin, maleimide resin, or polyester resin. Preferably, the thermosetting resin is epoxy resin. In addition, filler may be added to the sealing material. The filler is, for example, an insulating ceramic material having a high thermal conductivity.

The heat dissipation plate 3 has the shape of a rectangular flat plate in plan view. The heat dissipation plate 3 may have rounded corner portions in plan view. In addition, the heat dissipation plate 3 has insertion holes at locations corresponding to the fastening holes 21i in plan view. The rear surfaces of the semiconductor units 10a, 10b, and 10c are disposed on the front surface of the heat dissipation plate 3 via a bonding member, which will be described below. In addition, the rear surface of the case 20 is disposed on the front surface of the heat dissipation plate 3 via an adhesive, which will be described below. In this way, on the front surface of the heat dissipation plate 3, the semiconductor units 10a, 10b, and 10c are stored in the case 20. Next, by performing wiring on the semiconductor units 10a, 10b, and 10c and by sealing the unit storage spaces 21e, 21f, and 21g with a sealing member, the semiconductor module 2 is constructed. A cooling device, which cools the semiconductor module 2 by circulating refrigerant, may be attached to a region of the rear surface of the heat dissipation plate 3, the region corresponding to the area where the semiconductor module 2 is disposed. Alternatively, a plurality of heat dissipation fins may be formed on the rear surface of the heat dissipation plate 3. In this case, the semiconductor module 2 is cooled by air cooling.

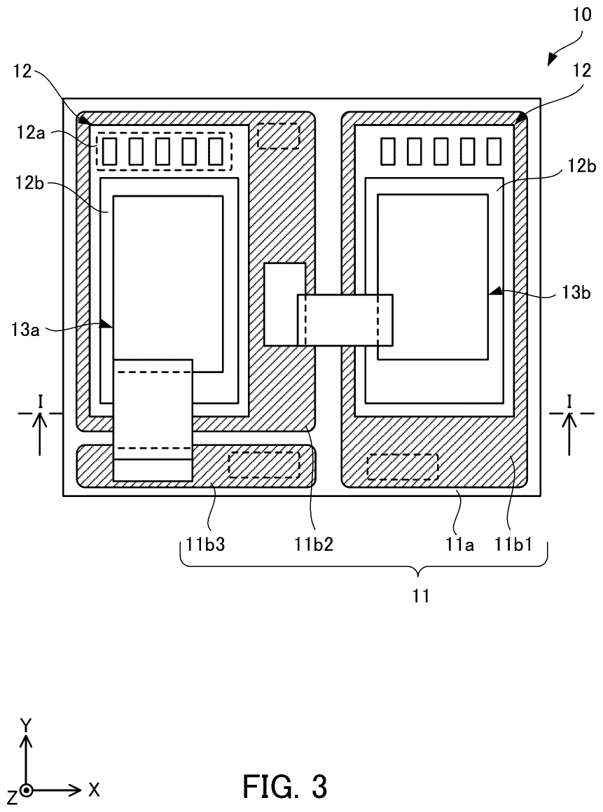

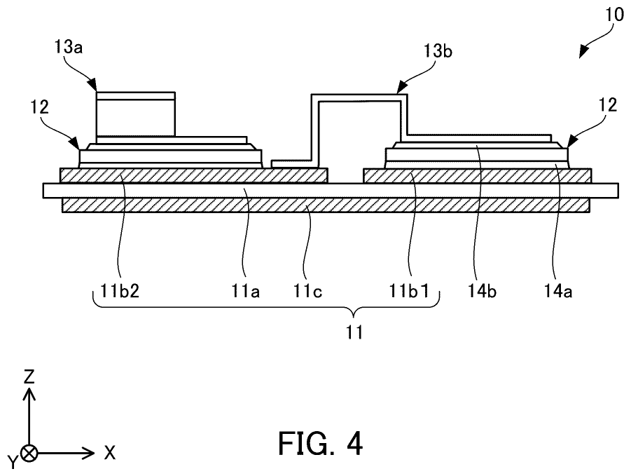

Next, the semiconductor units 10a, 10b, and 10c (semiconductor units 10) will be described with reference to FIGS. 3 and 4. FIG. 3 is a plan view of a semiconductor unit included in the semiconductor device according to the first embodiment. FIG. 4 is a sectional view of the semiconductor unit included in the semiconductor device according to the first embodiment. Specifically, FIG. 4 is a sectional view, taken along a dashed-dotted line I-I in FIG. 3.

This semiconductor unit 10 may be a device constituting a single-phase inverter circuit. The semiconductor unit 10 includes an insulated circuit board 11, two semiconductor chips 12, and lead frames 13a and 13b. The semiconductor chips 12 are bonded to the insulated circuit board 11 via a bonding member 14a.

The insulated circuit board 11 includes an insulating plate 11a, conductive circuit patterns 11b1, 11b2, and 11b3, and a metal plate 11c. The insulating plate 11a and the metal plate 11c each have a rectangular shape in plan view. The insulating plate 11a and the metal plate 11c may have rounded or chamfered corner portions. The metal plate 11c is smaller than the insulating plate 11a and is formed inside the insulating plate 11a in plan view.

The insulating plate 11a is made of an insulating material having an excellent thermal conductivity. The insulating plate 11a is made of a ceramic material, examples of which include aluminum oxide, aluminum nitride, and silicon nitride.

The conductive circuit patterns 11b1, 11b2, and 11b3 are each an example of a conductive plate, and are each formed on the front surface of the insulating plate 11a. The conductive circuit patterns 11b1, 11b2, and 11b3 are each made of a metal material having an excellent electrical conductivity. For example, this metal material is copper, aluminum, or an alloy containing at least one of these kinds of elements as its main component. The surface of each of the conductive circuit patterns 11b1, 11b2, and 11b3 may be plated to improve its corrosion resistance. The material used for this plating is, for example, nickel, a nickel-phosphorus alloy, or a nickel-boron alloy.

The conductive circuit pattern 11b1 is formed on approximately one half of the area of the front surface of the insulating plate 11a, the area occupied by the conductive circuit pattern 11b1 being located in the +X direction side of the insulating plate 11a. The area occupied by the conductive circuit pattern 11b1 ranges from the −Y direction side to the +Y direction side of the front surface of the insulating plate 11a. The conductive circuit pattern 11b1 has an area surrounded by a dashed line, and an end portion of a corresponding one of the first connection terminals 22a, 22b, and 22c is bonded to this area. Ultrasonic bonding is used for this bonding.

The conductive circuit pattern 11b2 occupies approximately the other half of the area of the front surface of the insulating plate 11a, the area occupied by the conductive circuit pattern 11b2 being located in the −x direction side of the insulating plate 11a. The conductive circuit pattern 11b2 ranges from the +Y direction side of the front surface of the insulating plate 11a to a line little before the −Y direction side of the front surface of the insulating plate 11a. The conductive circuit pattern 11b2 has an area surrounded by a dashed line, and an end portion of a corresponding one of the W-phase output terminal 24a, the V-phase output terminal 24b, and the U-phase output terminal 24c is bonded to this area. Ultrasonic bonding is used for this bonding.

The conductive circuit pattern 11b3 occupies an area surrounded by the conductive circuit patterns 11b1 and 11b2 on the front surface of the insulating plate 11a. The conductive circuit pattern 11b3 has an area surrounded by a dashed line, and an end portion of a corresponding one of the second connection terminals 23a, 23b, and 23c is bonded to this area. Ultrasonic bonding is used for this bonding.

These conductive circuit patterns 11b1, 11b2, and 11b3 are formed on the front surface of the insulating plate 11a as follows. First, a metal layer is formed on the front surface of the insulating plate 11a. Next, for example, by etching this metal layer, the conductive circuit patterns 11b1, 11b2, and 11b3, each of which has a predetermined shape, are obtained. Alternatively, the conductive circuit patterns 11b1, 11b2, and 11b3, which have been cut out of a metal layer in advance, may be bonded to the front surface of the insulating plate 11a by a brazing material such as silver. These conductive circuit patterns 11b1, 11b2, and 11b3 are only examples. The number, shape, size, or location of the conductive circuit patterns 11b1, 11b2, and 11b3 may be suitably determined, as appropriate.

The metal plate 11c is formed on the rear surface of the insulating plate 11a. The metal plate 11c has a rectangular shape. The area of the metal plate 11c is smaller than that of the insulating plate 11a and is larger than the area where the conductive circuit patterns 11b1, 11b2, and 11b3 are formed in plan view. The metal plate 11c may have rounded or chamfered corner portions. The metal plate 11c is formed on the entire area of the insulating plate 11a, excepting the periphery of the insulating plate 11a. The metal plate 11c is made of a material containing a metal material having an excellent thermal conductivity as its main component. For example, the metal material is copper, aluminum, or an alloy containing at least one of these kinds of elements.

For example, a direct copper bonding (DCB) board or an active metal brazed (AMB) board may be used as the insulated circuit board 11 having the above construction. The insulated circuit board 11 may be attached to the front surface of the heat dissipation plate 3 via a bonding member (not illustrated). The heat generated by the semiconductor chips 12 is transferred to the heat dissipation plate 3 via the conductive circuit patterns 11b1, 11b2, and 11b3, the insulating plate 11a, and the metal plate 11c, and is consequently dissipated.

The bonding member 14a and a bonding member 14b are solder. Lead-free solder is used as the solder. The main component of the lead-free solder is, for example, an alloy containing at least two of tin, silver, copper, zinc, antimony, indium, and bismuth. The solder may also contain additive, which is, for example, nickel, germanium, cobalt, or silicon. Because solder containing such additive as described above has improved wettability, luster, and bonding strength, the reliability is improved.

In addition, a brazing material or a thermal interface material may be used as the bonding member (not illustrated) for bonding the individual semiconductor unit 10 and the heat dissipation plate 3. For example, the main component of the brazing material is one of a tin alloy, an aluminum alloy, a titanium alloy, a magnesium alloy, a zirconium alloy, and a silicon alloy. For example, the thermal interface material is an adhesive material, such as an elastomer sheet, room temperature vulcanization (RTV) rubber, gel, or phase change material or is silicone to which a ceramic material has been added. By attaching the individual semiconductor unit 10 to the heat dissipation plate 3 via the brazing material or the thermal interface material as described above, the heat dissipation of the individual semiconductor unit 10 is improved.

The individual semiconductor chip 12 includes a power device element made of silicon. The power device element is a reverse-conducting (RC)-insulated gate bipolar transistor (IGBT). The RC-IGBT is a semiconductor element constituted by forming an IGBT functioning as a switching element and a free-wheeling diode (FWD) functioning as a diode element, which are connected in inverse parallel, on one chip. The semiconductor chip 12 includes, on its front surface, control electrodes 12a (gate electrodes) and an output electrode (an emitter electrode) functioning as the main electrode 12b. The semiconductor chip 12 includes, on its rear surface, an input electrode (a collector electrode) functioning as a main electrode. The control electrodes 12a are formed along one side of the front surface of the semiconductor chip 12. The output electrode is formed in a center portion of the front surface of the semiconductor chip 12.

Alternatively, the semiconductor chip 12 may be a power metal-oxide-semiconductor field-effect transistor (MOSFET) made of silicon carbide. A power MOSFET whose body diode functions as an FWD may be used. This semiconductor chip 12 includes an input electrode (a drain electrode) as a main electrode on its rear surface, and includes an output electrode (a source electrode) functioning as a main electrode 12b and control electrodes 12a (gate electrodes) on its front surface, for example.

Alternatively, the semiconductor chip 12 may include a set of a switching element and a diode element, each of which is made of silicon, instead of an RC-IGBT or a power MOSFET. The switching element is, for example, an IGBT or a power MOSFET. In this case, the semiconductor chip 12 includes, for example, an input electrode (a drain electrode or a collector electrode) as a main electrode on its rear surface, and includes control electrodes 12a (gate electrodes) and an output electrode (a source electrode or an emitter electrode) as a main electrode 12b on its front surface. For example, the diode element uses a Schottky barrier diode (SBD) or a P-intrinsic-N (PiN) diode as an FWD. The semiconductor chip 12 as described above includes an output electrode (a cathode electrode) as a main electrode on its rear surface and an input electrode (an anode electrode) as a main electrode on its front surface.

The lead frames 13a and 13b electrically connect and wire the semiconductor chips 12 and the conductive circuit patterns 11b1, 11b2, and 11b3. The lead frame 13a directly connects the main electrode 12b of the semiconductor chip 12 (on the conductive circuit pattern 11b2) and the conductive circuit pattern 11b3. The lead frame 13b directly connects the main electrode 12b of the semiconductor chip 12 (on the conductive circuit pattern 11b1) and the conductive circuit pattern 11b2.

One end portion of each of the lead frames 13a and 13b is bonded to the main electrode 12b of a corresponding one of the semiconductor chips 12 (on a corresponding one of the conductive circuit patterns 11b2 and 11b1) via a bonding member 14b. The bonding of the other end portion of each of the lead frames 13a and 13b to a corresponding one of the conductive circuit patterns 11b3 and 11b2 may be made by the above-described bonding member or ultrasonic bonding. If the bonding is made by ultrasonic bonding, the same ultrasonic bonding used for bonding the second bonding portion 23e of the second connection terminal 23b may be used.

The lead frames 13a and 13b are each made of a metal material having an excellent electrical conductivity. For example, this metal material is copper, aluminum, or an alloy containing at least one of these kinds of elements as its main component. The surface of each of the lead frames 13a and 13b may be plated to improve its corrosion resistance. The material used for this plating is, for example, nickel, a nickel-phosphorus alloy, or a nickel-boron alloy.

In addition, the control electrodes 12a of the semiconductor chips 12 of the semiconductor units 10a, 10b, and 10c stored in the unit storage spaces 21e, 21f, and 21g of the case 20 are mechanically and electrically connected to the other ends of the control terminals 25a, 25b, and 25c by wires 26. The main component of each of these wires 26 is a material having an excellent electrical conductivity. The material is, for example, gold, copper, aluminum, or an alloy containing at least one of these kinds of elements. Preferably, the individual wire 26 is made of an aluminum alloy containing a minute amount of silicon.

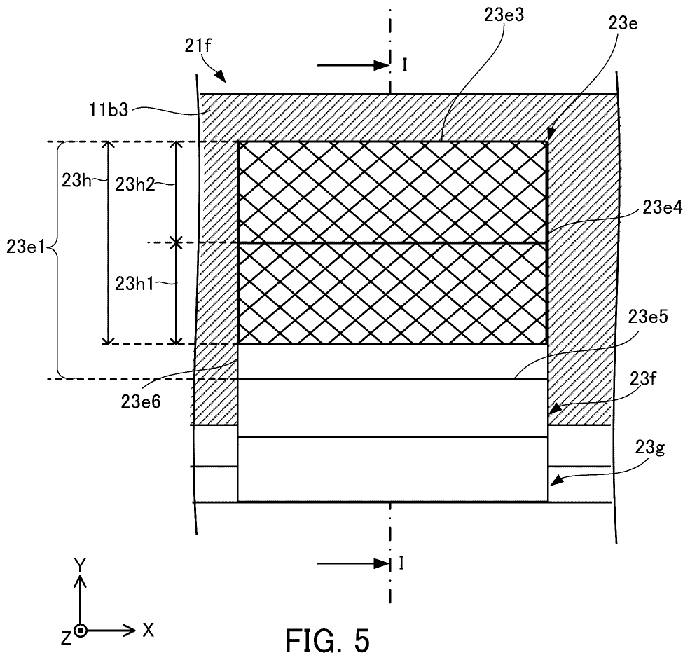

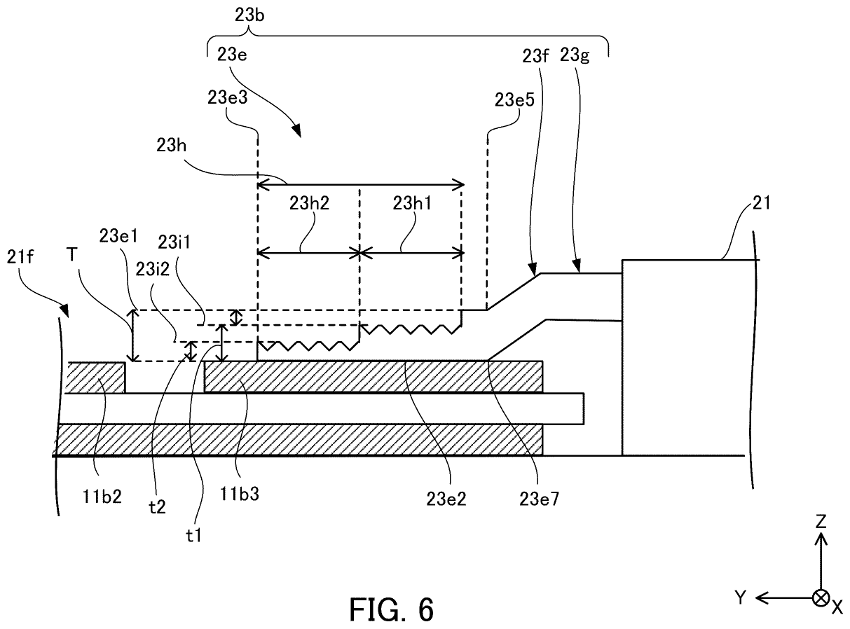

Next, bonding of the first bonding portions of the first connection terminals 22a, 22b, and 22c, the second bonding portions of the second connection terminals 23a, 23b, and 23c, and the third bonding portions of the W-phase output terminal 24a, the V-phase output terminal 24b, and the U-phase output terminal 24c to the semiconductor units 10 will be described. Hereinafter, as an example, details of the second bonding portion 23e of the second connection terminal 23b bonded to the conductive circuit pattern 11b3 included in the semiconductor unit 10b will be described with reference to FIGS. 5 and 6.

FIG. 5 is a plan view of a connection terminal bonded to a conductive circuit pattern included in the semiconductor device according to the first embodiment. FIG. 6 is a sectional view of the connection terminal bonded to the conductive circuit pattern included in the semiconductor device according to the first embodiment. Specifically, FIG. 5 is an enlarged view of the second bonding portion 23e, which is enclosed by a dashed line in FIG. 1 and included in the second connection terminal 23b. FIG. 6 is a sectional view, taken along a dashed-dotted line I-I in FIG. 5.

The second connection terminal 23b integrally includes the second bonding portion 23e, a second ramp portion 23f, and a second wiring portion 23g. Overall, the second bonding portion 23e, the second ramp portion 23f, and the second wiring portion 23g may have the same thickness. In addition, overall, the +X direction width of the second bonding portion 23e, the second ramp portion 23f, and the second wiring portion 23g may be the same in plan view of the second connection terminal 23b.

The second bonding portion 23e has the shape of a flat plate. The second bonding portion 23e has a rectangular top surface 23e1 and a rectangular bottom surface 23e2 in plan view, and also has a bonding side portion 23e6, a bonding front end portion 23e3, a bonding side portion 23e4, which constitute three side surfaces in the +Y direction and the +X directions of the top surface 23e1 and the bottom surface 23e2. As illustrated in FIG. 6, the second bonding portion 23e has a thickness T from the bottom surface 23e2 to the top surface 23e1. For example, the thickness T may be between 1 mm and 2 mm, inclusive.

The second ramp portion 23f is integrally connected to an end portion of the top surface 23e1 of the second bonding portion 23e in plan view, the end portion being opposite the bonding front end portion 23e3. The boundary between the top surface 23e1 of the second bonding portion 23e and the second ramp portion 23f is a bonding rear end portion 23e5. The bonding rear end portion 23e5 is one end portion of the top surface 23e1 of the second bonding portion 23e, and the bonding front end portion 23e3 is located opposite the bonding rear end portion 23e5 of the top surface 23e1.

The boundary between the bottom surface 23e2 of the second bonding portion 23e and the second ramp portion 23f is also a heel portion 23e7. The heel portion 23e7 is an end portion of the bottom surface 23e2 and is located opposite the bonding front end portion 23e3 of the second bonding portion 23e.

The second bonding portion 23e of the second connection terminal 23b is bonded to the conductive circuit pattern 11b3 by ultrasonic bonding. An indentation area 23h including indentations obtained by transferring the shape of the tip of a bonding tool 4 at ultrasonic bonding is formed on the top surface 23e1. In addition, an area of the bottom surface 23e2, the area corresponding to the indentation area 23h, is bonded to the conductive circuit pattern 11b3 by ultrasonic bonding. Details of the indentation area 23h will be described below.

The bonding front end portion 23e3 is the +Y direction end portion (front end portion) of the second bonding portion 23e in plan view. The bonding front end portion 23e3 faces the inside of the unit storage space 21f (in the +Y direction) when the second bonding portion 23e is disposed on the conductive circuit pattern 11b3.

The bonding rear end portion 23e5 is one end portion of the top surface 23e1 of the second bonding portion 23e, and is the boundary between the top surface 23e1 and the second ramp portion 23f. The bonding rear end portion 23e5 is located near the (−Y direction) inner wall of the unit storage space 21f when the second bonding portion 23e is disposed on the conductive circuit pattern 11b3. The heel portion 23e7 is one end portion of the bottom surface 23e2 of the second bonding portion 23e, and is the boundary between the bottom surface 23e2 and the second ramp portion 23f. The heel portion 23e7 also faces the (−Y direction) inner wall of the unit storage space 21f when the second bonding portion 23e is disposed on the conductive circuit pattern 11b3.

The bonding side portions 23e4 and 23e6 are perpendicular to the top surface 23e1, the bottom surface 23e2, and the bonding front end portion 23e3, and connect the top surface 23e1, the bottom surface 23e2, and the bonding front end portion 23e3. The portions where any two of the top surface 23e1, the bottom surface 23e2, and the bonding front end portion 23e3, the bonding side portion 23e4, and the bonding side portion 23e6 are connected to each other may be right-angled or rounded.

The second ramp portion 23f links the second bonding portion 23e and the second wiring portion 23g. The second ramp portion 23f is integrally connected to an end portion of the second bonding portion 23e, the end portion being opposite the bonding front end portion 23e3. The second ramp portion 23f extends in the +Z direction from the top surface 23e1 of the second bonding portion 23e. The angle at which the second ramp portion 23f extends from the top surface 23e1 of the second bonding portion 23e may be between 30° and 90°, inclusive. The angle illustrated in FIG. 6 at which the second ramp portion 23f extends from the top surface 23e1 is an example.

The second wiring portion 23g is connected to the (−Y direction) end portion of the second ramp portion 23f, is parallel to the insulated circuit board 11 in a side view, and penetrates into the outer frame 21 from the unit storage space 21f. The second wiring portion 23g extends inside the outer frame 21 and is exposed to the outside on the front surface of the outer frame 21.

Next, the indentation area 23h formed on the top surface 23e1 of the second bonding portion 23e of the second connection terminal 23b will be described. The top surface 23e1 of the second bonding portion 23e of the second connection terminal 23b is pressed by a pressing surface of the tip of the following bonding tool for ultrasonic bonding, and the second bonding portion 23e is consequently bonded to the conductive circuit pattern 11b3 of the insulated circuit board 11. Details of the ultrasonic bonding will be described below.

In this pressing step, the indentation area 23h including indentations obtained by transferring the shape of the tip of the bonding tool is formed on the top surface 23e1 of the second bonding portion 23e of the second connection terminal 23b. The indentation area 23h has a rectangular shape in plan view, as illustrated in FIG. 5. The (+Y direction) length of the indentation area 23h is from the bonding front end portion 23e3 of the top surface 23e1 to a line little before the bonding rear end portion 23e5 in plan view. The (+X direction) width of the indentation area 23h is from the bonding side portion 23e4 to the bonding side portion 23e6 of the top surface 23e1 in plan view.

The indentation area 23h is constituted by a plurality of sub-indentation areas whose thicknesses from the bottom surface 23e2 are less than the thickness T of the second bonding portion 23e. These sub-indentation areas may be formed in a line from an area near the bonding rear end portion 23e5 to the bonding front end portion 23e3 of the top surface 23e1 in the indentation area 23h of the top surface 23e1 in plan view. That is, the plurality of sub-indentation areas formed in a line has the same ±X direction width, which matches the ±X direction width of the indentation area 23h. The sum of the ±Y direction lengths of the plurality of sub-indentation areas is the ±Y direction length of the indentation area 23h. That is, of all the plurality of sub-indentation areas, the +Y direction end portion of the tip sub-indentation area in the +Y direction matches the bonding front end portion 23e3. In addition, of all the plurality of sub-indentation areas, the −Y direction end portion of the tip sub-indentation area in the −Y direction matches the end portion of the indentation area 23h, the end portion being near the bonding rear end portion 23e5. Each of the plurality of sub-indentation areas may have a different ±Y direction length.

In the first embodiment, the plurality of sub-indentation areas are first and second sub-indentation areas 23h1 and 23h2. In this case, in the indentation area 23h, the second sub-indentation area 23h2 is formed near the bonding front end portion 23e3, and the first sub-indentation area 23h1 is formed near the bonding rear end portion 23e5 in plan view. In addition, in plan view, the area (first area) of the first sub-indentation area 23h1, and the area (second area) of the second sub-indentation area 23h2 may be equal to each other.

In this case, the +Y direction length of the first sub-indentation area 23h1 is equal to the +Y direction length of the second sub-indentation area 23h2.

In addition, a first thickness t1 from the bottom surface 23e2 to a first upper end 23i1 in the first sub-indentation area 23h1 is greater than a second thickness t2 from the bottom surface 23e2 to a second upper end 2312 in the second sub-indentation area 23h2.

The indentations included in the indentation area 23h may have different shapes, instead of a uniform shape. Thus, the thickness from the bottom surface 23e2 of the second bonding portion 23e to the top of each indentation in the indentation area 23h varies, depending on the location. Therefore, the above-described first upper end 23i1 is the average location of the tops of the plurality of indentations included in the first sub-indentation area 23h1. The same holds true to the second upper end 2312 of the second sub-indentation area 23h2.

In addition, in the first sub-indentation area 23h1, a first depth from the top surface 23e1 to the first upper end 23i1 is less (shallower) than a second depth from the top surface 23e1 to the second upper end 2312 in the second sub-indentation area 23h2. The first depth in the first sub-indentation area 23h1 is, for example, approximately 300 μm, and the second depth in the second sub-indentation area 23h2 is, for example, approximately 700 μm.

In addition, there is a difference in level between the first sub-indentation area 23h1 and the second sub-indentation area 23h2. The height of the level difference is the difference between the second thickness t2 from the bottom surface 23e2 to the second upper end 2312 and the first thickness t1 from the bottom surface 23e2 to the first upper end 2311. This difference may be, for example, between 0.1 mm and 0.4 mm, inclusive.

An area of the bottom surface 23e2 of the second bonding portion 23e of the second connection terminal 23b, the area corresponding to the indentation area 23h, is bonded to the conductive circuit pattern 11b3. In particular, a first bonding area and a second bonding area of the bottom surface 23e2 of the second bonding portion 23e of the second connection terminal 23b, the first bonding area and the second bonding area corresponding to the first sub-indentation area 23h1 and the second sub-indentation area 23h2, are bonded to the conductive circuit pattern 11b3. The second bonding area corresponding to the second sub-indentation area 23h2 is larger than the first bonding area corresponding to the first sub-indentation area 23h1.

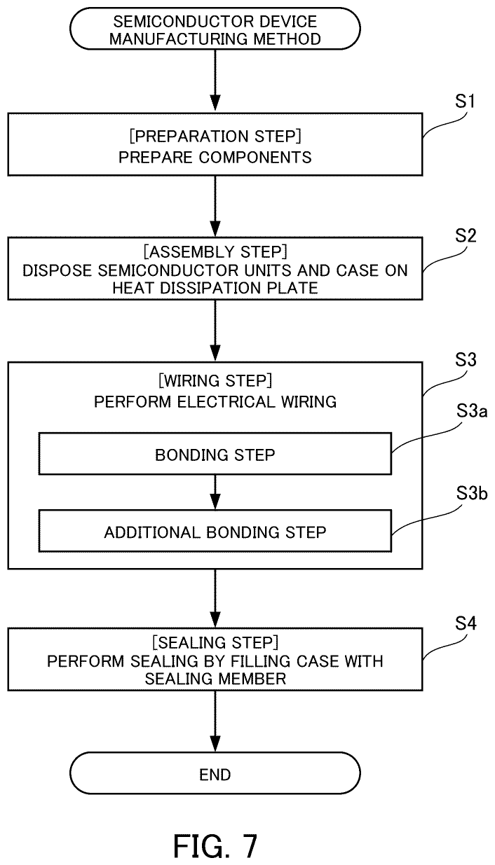

Next, a manufacturing method of the semiconductor device 1 will be described with reference to FIG. 7. FIG. 7 is a flowchart illustrating a semiconductor device manufacturing method according to the first embodiment. The first embodiment assumes that the plurality of sub-indentation areas are the first and second sub-indentation areas 23h1 and 23h2.

First, a preparation step of preparing components of the semiconductor device 1 and manufacturing apparatuses for manufacturing the semiconductor device 1 is performed (step S1 in FIG. 7). For example, the individual semiconductor chip 12, the individual insulated circuit board 11, the heat dissipation plate 3, the case 20, the sealing material, the lead frames 13a and 13b, and the individual terminals (the first connection terminals 22a, 22b, and 22c, the second connection terminals 23a, 23b, and 23c, the W-phase output terminal 24a, the V-phase output terminal 24b, and the U-phase output terminal 24c), which are components of the semiconductor device 1, are prepared. The individual semiconductor unit 10 may be assembled in advance by bonding the corresponding semiconductor chips 12 to the corresponding insulated circuit board 11 and by bonding the corresponding lead frames 13a and 13b to the semiconductor chips 12. In addition to these components, apparatuses used in the manufacturing method of the semiconductor device 1 may also be prepared. Examples of these apparatuses include an ultrasonic bonding apparatus, a wire bonding apparatus, and a dispensing apparatus for resin sealing. In addition to the above-described components and apparatuses relating to the manufacturing, needed components, etc., may also be prepared.

Next, an assembly step of bonding the semiconductor units 10 to the heat dissipation plate 3 and disposing the case 20 on the heat dissipation plate 3 is performed (step S2 in FIG. 7). The semiconductor units 10 are bonded to the heat dissipation plate 3 via the above-described bonding member. The case 20 is attached onto the heat dissipation plate 3 via an adhesive. As a result, the semiconductor units 10 are stored in the unit storage spaces 21e, 21f, and 21g of the case 20.

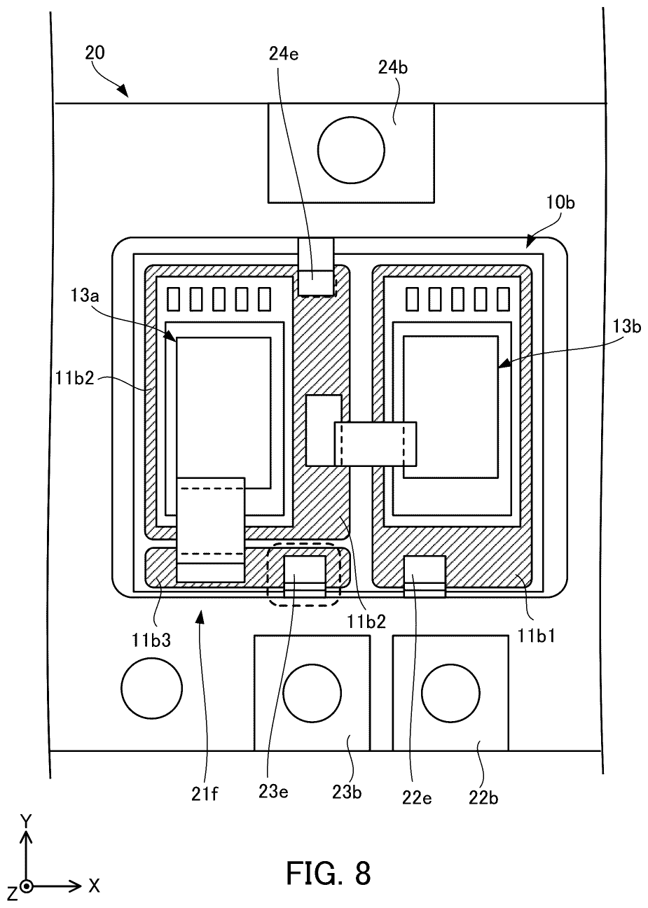

The semiconductor units 10 stored in the case 20 as described above will be described with reference to FIG. 8. FIG. 8 is a plan view of a main portion after the assembly step included in the semiconductor device manufacturing method according to the first embodiment. FIG. 8 illustrates the semiconductor unit 10b stored in the unit storage space 21f of the case 20. The semiconductor units 10a and 10c are stored in their respective unit storage spaces 21e and 21g in the same way.

After step S2 in FIG. 7, in the unit storage space 21f, the first bonding portion 22e included in the first connection terminal 22b is disposed on the conductive circuit pattern 11b1, as illustrated in FIG. 8. The third bonding portion 24e of the V-phase output terminal 24b is disposed on the conductive circuit pattern 11b2. The second bonding portion 23e included in the second connection terminal 23b is disposed on the conductive circuit pattern 11b3. In addition, one end portion of each of the lead frames 13a and 13b is bonded to the main electrode 12b of the semiconductor chip 12 on a corresponding one of the conductive circuit patterns 11b2 and 11b1 via the bonding member 14b (see FIG. 4). The other end portion of each of the lead frames 13a and 13b is bonded to a corresponding one of the conductive circuit patterns 11b3 and 11b2. The other end portion of each of the lead frames 13a and 13b may be bonded to a corresponding one of the conductive circuit patterns 11b3 and 11b2 by using the above-described bonding member or by using ultrasonic bonding. If the bonding is performed by using ultrasonic bonding, the same ultrasonic bonding (steps S3a and S3b in FIG. 7) as that used for the second bonding portion 23e of the second connection terminal 23b may be performed.

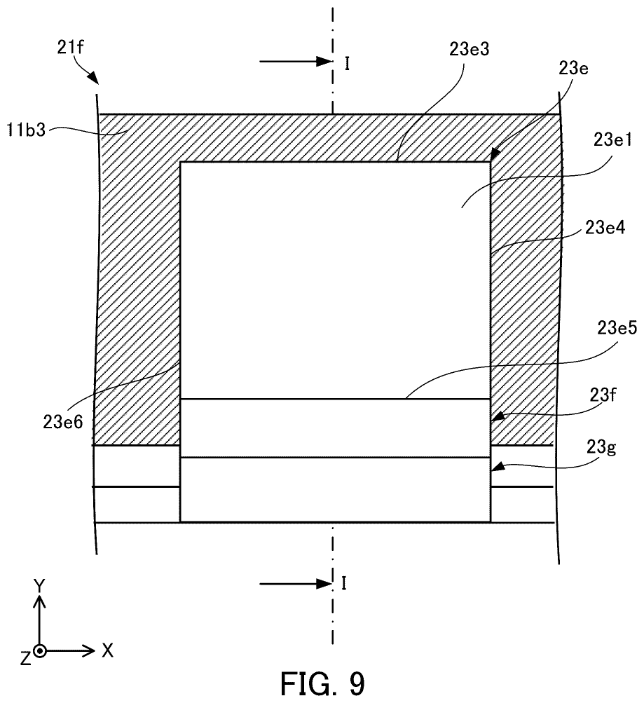

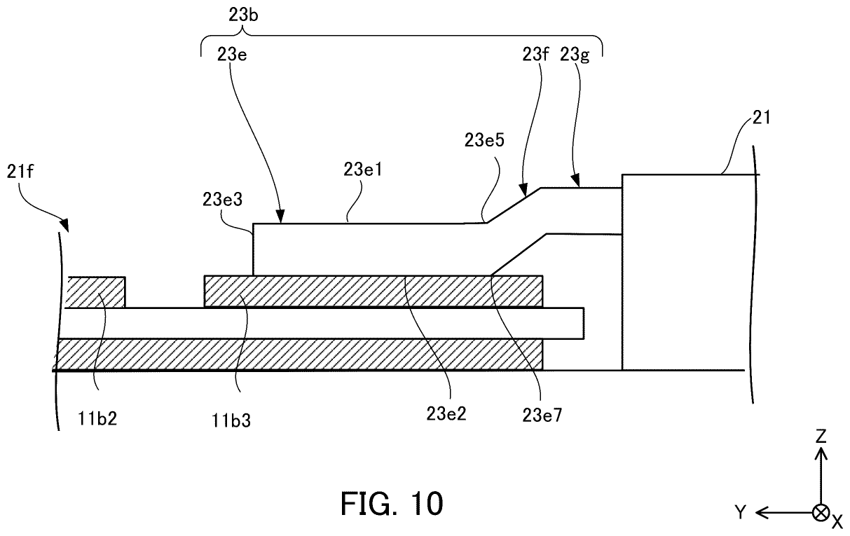

Hereinafter, details of the second connection terminal 23b disposed on a semiconductor unit 10 will be described with reference to FIGS. 9 and 10, as an example of a semiconductor unit 10 stored in the case 20. FIG. 9 is a plan view of a connection terminal disposed on a conductive circuit pattern after the assembly step in the semiconductor device manufacturing method according to the first embodiment. FIG. 10 is a sectional view of the connection terminal disposed on the conductive circuit pattern after the assembly step in the semiconductor device manufacturing method according to the first embodiment. Specifically, FIG. 9 is an enlarged view of the second bonding portion 23e, which is indicated by a dashed line in FIG. 8 and which is included in the second connection terminal 23b. FIG. 10 is a sectional view, taken along a dashed-dotted line I-I in FIG. 9.

As described above, the second connection terminal 23b integrally includes the second bonding portion 23e, the second ramp portion 23f, and the second wiring portion 23g. FIGS. 9 and 10 illustrate the second bonding portion 23e of the second connection terminal 23b before ultrasonic bonding is performed. Thus, the top surface 23e1 does not have any indentations and may be substantially flat. In addition, although the bottom surface 23e2 of the second bonding portion 23e has not yet been bonded to the conductive circuit pattern 11b3, the bottom surface 23e2 is in contact with the conductive circuit pattern 11b3. At this point of time, there may be a little gap between the bottom surface 23e2 of the second bonding portion 23e and the conductive circuit pattern 11b3.

The second connection terminal 23b is disposed on the conductive circuit pattern 11b3 in the above-described state. Although not illustrated, the second connection terminals 23a and 23c, the first connection terminals 22a, 22b, and 22c, the W-phase output terminal 24a, the V-phase output terminal 24b, and the U-phase output terminal 24c are disposed in the same way as described above.

Next, a wiring step of wiring the semiconductor units 10 is performed (step S3 in FIG. 7). In this wiring step, various kinds of terminals and the semiconductor units 10 are electrically wired by using wiring members.

First, the control electrodes 12a of the semiconductor chips 12 included in the semiconductor units 10 stored in the case 20 are connected to the control terminals 25a, 25b, and 25c by the wires 26, which are an example of the wiring members, by using a bonding apparatus (see FIG. 1).

In addition, the individual bonding portions of the individual terminals (the first connection terminals 22a, 22b, and 22c, the second connection terminals 23a, 23b, and 23c, the W-phase output terminal 24a, the V-phase output terminal 24b, and the U-phase output terminal 24c) disposed on the conductive circuit patterns 11b1, 11b2, and 11b3 of the semiconductor units 10 are bonded to the conductive circuit patterns 11b1, 11b2, and 11b3 by using ultrasonic bonding of an ultrasonic bonding apparatus.

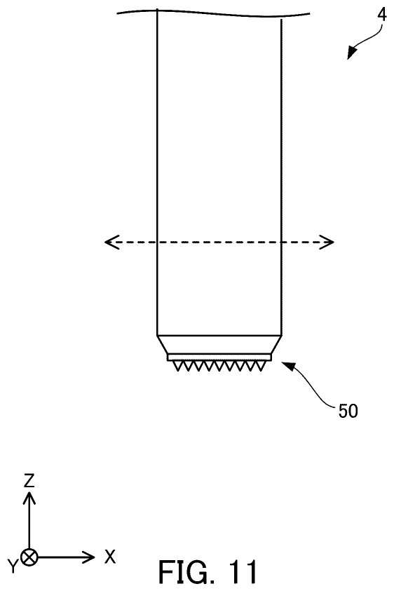

Hereinafter, a bonding tool included in the ultrasonic bonding apparatus will be described with reference to FIG. 11. FIG. 11 is a side view of a bonding tool used in the wiring step included in the semiconductor device manufacturing method according to the first embodiment. FIG. 11 is side view of the tip of the bonding tool 4, seen in the +Y direction.

The bonding tool 4 illustrated in FIG. 11 is included in the ultrasonic bonding apparatus. The bonding tool 4 has a columnar shape and is vibrated in a predetermined direction by a vibration generator also included in the ultrasonic bonding apparatus. The columnar shape may be a cylindrical shape or a polygonal shape. The predetermined direction may be a direction parallel to the X-Y plane.

The bonding tool 4 includes a pressing tip portion 50 at its tip (in the −Z direction in FIG. 11). The pressing tip portion 50 is brought in contact with a bonding target object and presses the bonding target object while vibrating in a specified direction. In this way, bonding is performed.

The pressing tip portion 50 includes a plurality of protrusions. Examples of the material of the plurality of protrusions may include a cemented carbide material. For example, the cemented carbide material is tungsten, tungsten carbide, or an alloy containing at least one of these kinds of elements.

The plurality of protrusions may be formed in a zigzag pattern or in a grid pattern on the −Z direction end surface of the pressing tip portion 50. The individual protrusion may have a rectangular pyramid shape, a polygonal pyramid shape, or a conical shape. The plurality of protrusions have approximately the same height. This height is the length from the bottom surface of the pressing tip portion 50 of the bonding tool 4 to the lower ends of the protrusions. The lower ends of the plurality of protrusions of the pressing tip portion 50 of the bonding tool 4 are on approximately the same plane, which will be referred to as “pressing surface”.

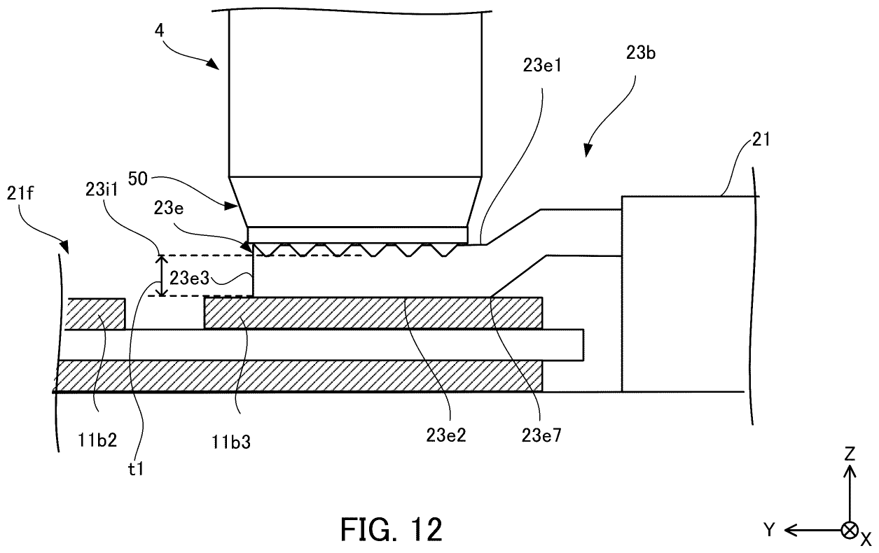

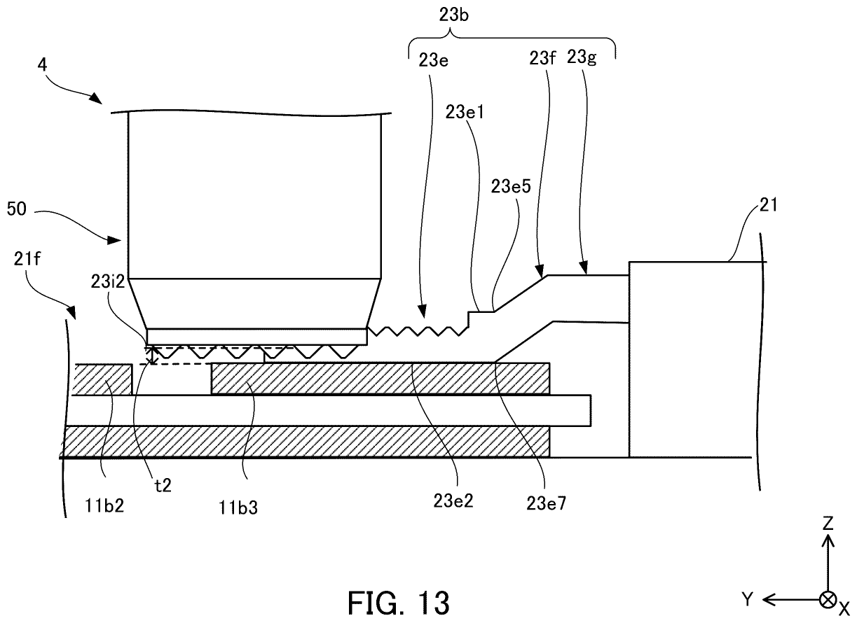

The ultrasonic bonding executed by the bonding tool 4 in the wiring step will be described with reference to FIGS. 12 and 13. FIG. 12 illustrates a bonding step included in the wiring step in the semiconductor device manufacturing method according to the first embodiment. FIG. 13 illustrates an additional bonding step included in the wiring step in the semiconductor device manufacturing method according to the first embodiment. Specifically, FIG. 12 illustrates ultrasonic bonding for weakly pressing the second bonding portion 23e in step S3a in FIG. 7, and FIG. 13 illustrates ultrasonic bonding for deeply pressing the second bonding portion 23e in step S3b in FIG. 7. Hereinafter, the bonding of the second bonding portion 23e of the second connection terminal 23b to the conductive circuit pattern 11b3 will be described. The bonding of the other bonding portions to the conductive circuit patterns 11b1 and 11b2 may be performed in the same way.

As illustrated in FIGS. 9 and 10, ultrasonic bonding (bonding step) is performed on the second bonding portion 23e of the second connection terminal 23b, the second bonding portion 23e being disposed on the conductive circuit pattern 11b3 (step S3a in FIG. 7). First, the pressing tip portion 50 of the bonding tool 4 is set on the top surface 23e1 of the second bonding portion 23e. In this step, the pressing tip portion 50 of the bonding tool 4 covers an area of a predetermined length from the bonding front end portion 23e3 on the top surface 23e1 of the second bonding portion 23e toward the bonding rear end portion 23e5. The area between the bonding side portions 23e4 and 23e6 on the top surface 23e1 of the second bonding portion 23e is covered by the pressing tip portion 50.

In this state, the second bonding portion 23e of the second connection terminal 23b is pressed against the conductive circuit pattern 11b3 of the insulated circuit board 11 while being vibrated by the pressing tip portion 50 of the bonding tool 4 with a predetermined vibration frequency. As a result, the pressing tip portion 50 of the bonding tool 4 penetrates into the top surface 23e1 of the second bonding portion 23e of the second connection terminal 23b. As illustrated in FIG. 12, the top surface 23e1 is pressed until the thickness from the bottom surface 23e2 to the first upper end 23i1 reaches the first thickness t1. After the pressing, the indentation area 23h including indentations obtained by transferring the shape of the pressing tip portion 50 of the bonding tool 4 is formed in the pressed top surface 23e1 of the second bonding portion 23e. As a result, the bottom surface 23e2 of the second bonding portion 23e is bonded to the conductive circuit pattern 11b3.

Next, additional ultrasonic bonding (additional bonding step) in which part of the indentation area 23h formed on the top surface 23e1 of the second bonding portion 23e of the second connection terminal 23b is pressed more deeply is performed (step S3b in FIG. 7). First, the bonding tool 4 in the state illustrated in FIG. 12 is moved from the second bonding portion 23e in the +Z direction, and is separated from the second bonding portion 23e. Next, the bonding tool 4 is moved linearly toward the bonding front end portion 23e3 by approximately half the +Y direction length of the indentation area 23h, so as to cover the bonding front end portion 23e3 side of the second bonding portion 23e in the indentation area 23h. The area that is not covered in the indentation area 23h is the first sub-indentation area 23h1.

In this state, the pressing tip portion 50 of the bonding tool 4 presses the second bonding portion 23e of the second connection terminal 23b against the conductive circuit pattern 11b3 of the insulated circuit board 11 while vibrating the second bonding portion 23e with a predetermined vibration frequency. Consequently, the pressing tip portion 50 of the bonding tool 4 penetrates into the indentation area 23h on the top surface 23e1 of the second bonding portion 23e of the second connection terminal 23b. As illustrated in FIG. 13, the second bonding portion 23e is pressed until the thickness from the bottom surface 23e2 to the second upper end 2312 reaches the second thickness t2. In this way, the second sub-indentation area 23h2 having the second thickness t2 less than the first thickness t1 is formed in the area of the indentation area 23h, the area being other than the first sub-indentation area 23h1.

As described above, an area of the bottom surface 23e2 of the second bonding portion 23e of the second connection terminal 23b, the area corresponding to the indentation area 23h, is bonded to the conductive circuit pattern 11b3. In particular, the first bonding area and the second bonding area of the bottom surface 23e2 of the second bonding portion 23e of the second connection terminal 23b are bonded to the conductive circuit pattern 11b3, the first bonding area corresponding to the first sub-indentation area 23h1 and the second bonding area corresponding to the second sub-indentation area 23h2. The second bonding area corresponding to the second sub-indentation area 23h2 is larger than the first bonding area corresponding to the first sub-indentation area 23h1.

In this way, the first bonding area of the bottom surface 23e2 under the first sub-indentation area 23h1 of the second bonding portion 23e is bonded to the conductive circuit pattern 11b3. In addition, the second bonding area of the bottom surface 23e2 under the second sub-indentation area 23h2 of the second bonding portion 23e is bonded to the conductive circuit pattern 11b3. The area in which the bottom surface 23e2 of the second bonding portion 23e is bonded to the conductive circuit pattern 11b3 depends on the depth made by the pressing performed by the ultrasonic bonding. The second sub-indentation area 23h2 pressed more deeply achieves a larger bonding area than the first sub-indentation area 23h1 pressed more shallowly. Thus, the second bonding area corresponding to the second sub-indentation area 23h2 is larger than the first bonding area corresponding to the first sub-indentation area 23h1, and has a greater bonding strength than the first bonding area.

In addition, since the pressing tip portion 50 of the bonding tool 4 has been moved linearly in the direction of the bonding front end portion 23e3 by approximately half the +Y direction length of the indentation area 23h, the +Y direction length of the first sub-indentation area 23h1 is equal to the +Y direction length of the second sub-indentation area 23h2. Thus, the first area of the first sub-indentation area 23h1 is equal to the second area of the second sub-indentation area 23h2. In addition, although the first area of the first sub-indentation area 23h1 and the second area of the second sub-indentation area 23h2 are formed to be equal to each other, the first area and the second area may be formed to differ from each other, depending on the movement distance of the pressing tip portion 50 of the bonding tool 4.

The first embodiment assumes that the plurality of sub-indentation areas are the first and second sub-indentation areas 23h1 and 23h2. In the case where a plurality of sub-indentation areas are formed in the indentation area 23h, after the above-described bonding step is performed in step S3a, the additional bonding step is performed repeatedly, in which the pressing tip portion 50 of the bonding tool 4 is moved linearly in the direction from the direction of the bonding rear end portion 23e5 toward the bonding front end portion 23e3 and the pressing is then performed. In this way, at least one sub-indentation area may be formed in a line in the direction extending from the bonding rear end portion 23e5 to the bonding front end portion 23e3. In this case, too, the areas of the plurality of sub-indentation areas may be equal to or different from each other, depending on the movement distance of the pressing tip portion 50 of the bonding tool 4.

Next, a sealing step of injecting a sealing member into the unit storage spaces 21e, 21f, and 21g storing the semiconductor units 10 in the case 20 and sealing the semiconductor units 10 is performed (step S4 in FIG. 7). After the unit storage spaces 21e, 21f, and 21g are filled with the sealing member, the sealing member is cured to seal the semiconductor units 10, etc. As a result, the semiconductor device 1 is obtained.

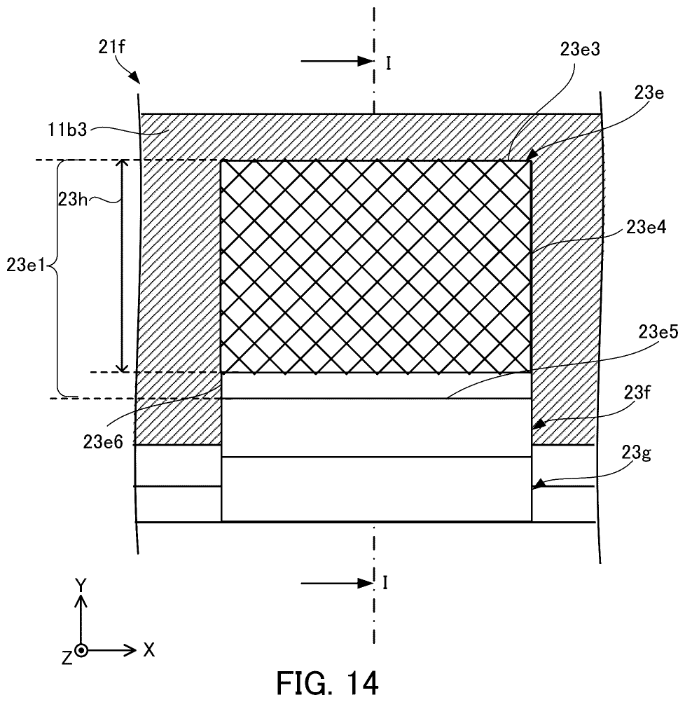

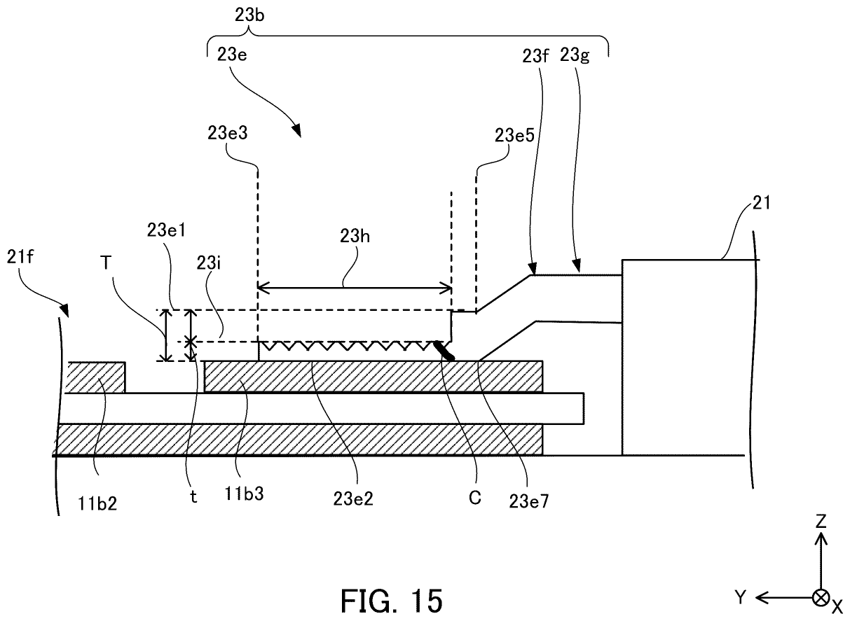

Hereinafter, a second connection terminal 23b included in a semiconductor device according to a reference example 1 will be described. FIG. 14 is a plan view of a connection terminal bonded to a conductive circuit pattern included in a semiconductor device according to a reference example 1. FIG. 15 is a sectional view of the connection terminal bonded to the conductive circuit pattern included in the semiconductor device according to the reference example 1. Specifically, FIG. 15 is a sectional view, taken along a dashed-dotted line I-I in FIG. 14. FIGS. 14 and 15 correspond to FIGS. 5 and 6, respectively.

The semiconductor device according to the reference example 1 may also be manufactured in accordance with the flowchart in FIG. 7, except that the additional bonding step (step S3b) included in the wiring step (step S3) is not performed. In the bonding step (step S3a), the ultrasonic bonding for deeply pressing a second bonding portion 23e is performed. In the reference example 1, only an indentation area 23h without any difference in level is formed. Except these points, the semiconductor device and the manufacturing method thereof are the same as the semiconductor device 1 and the manufacturing method thereof according to the first embodiment.

The entire indentation area 23h formed in a top surface 23e1 of the second bonding portion 23e according to the reference example 1 has a thickness t from a bottom surface 23e2 to an upper end 23i. The thickness t of the indentation area 23h is sufficiently less than a thickness T of the second bonding portion 23e. The thickness t of the indentation area 23h may be, for example, approximately the second thickness t2 according to the first embodiment.

The second bonding portion 23e included in the second connection terminal 23b according to the reference example 1 includes a portion where the indentation area 23h is formed, and also includes a portion where the indentation area 23h is not formed. The portion where the indentation area 23h is formed is sufficiently thinner than the other portion where the indentation area 23h is not formed. For example, a bonding rear end portion 23e5 and a heel portion 23e7 of the second bonding portion 23e are connected to a second ramp portion 23f, and have a sufficient thickness, compared with the portion where the indentation area 23h is formed. Thus, as illustrated in FIG. 15, if stress is applied to the second bonding portion 23e and the second ramp portion 23f of the second connection terminal 23b, the stress is concentrated on the intersection of the −Y direction end portion of the indentation area 23h and the top surface 23e1. This intersection is the boundary between the thin portion where the indentation area 23h of the second bonding portion 23e is formed and the portion where the indentation area 23h is not formed. A crack C could occur at this intersection. If the stress is continuously applied, this crack C extends from the intersection in the thickness direction of the second bonding portion 23e of the second connection terminal 23b, that is, in the −Z direction, and the second connection terminal 23b could finally fracture, leaving the portion where the indentation area 23h is formed on the conductive circuit pattern 11b3. Thus, according to the reference example 1, since the second bonding portion 23e of the second connection terminal 23b is pressed by the ultrasonic bonding and consequently includes a thin portion, the crack C could occur and extend. As a result, the fatigue life of the second connection terminal 23b deteriorates, and the long-term reliability of the semiconductor device deteriorates.

On the other hand, the semiconductor device 1 according to the first embodiment includes the conductive circuit pattern 11b3 and the second connection terminal 23b including the second bonding portion 23e which has the bottom surface 23e2 that is bonded to the conductive circuit pattern 11b3 and the top surface 23e1 that includes the indentation area 23h in which indentations are formed, which has a flat plate shape, and which is rectangular in plan view, and including the second ramp portion 23f which is integrally connected to the bonding rear end portion 23e5 of the second bonding portion 23e, the bonding rear end portion 23e5 being one end portion of the top surface 23e1, and which extends upward from the bonding rear end portion 23e5 of the top surface 23e1. The indentation area 23h of the second bonding portion 23e of the second connection terminal 23b is formed by the first and second sub-indentation areas 23h1 and 23h2 whose thicknesses from the bottom surface 23e2 are less than the thickness T from the bottom surface 23e2 to the top surface 23e1. The first thickness t1 from the bottom surface 23e2 to the first upper end 23i1 in the first sub-indentation area 23h1 is greater than the second thickness t2 from the bottom surface 23e2 to the second upper end 2312 in the second sub-indentation area 23h2.

Even with this second connection terminal 23b according to the first embodiment, as is the case with the above-described reference example 1, stress is concentrated on the intersection of the −Y direction end portion of the indentation area 23h and the top surface 23e1. However, in the case of the second connection terminal 23b according to the first embodiment, the thickness t1 of the first sub-indentation area 23h1 included in the indentation area 23h with respect to the thickness T from the bottom surface 23e2 to the top surface 23e1 of the second bonding portion 23e is greater than the case according to the reference example 1. Thus, a sufficient thickness is obtained for the second connection terminal 23b at the above-described intersection where the crack C occurs. Thus, when the crack C occurs, the stress is distributed from the above-described intersection in the thickness direction of the second bonding portion 23e and the interface direction of the second bonding portion 23e and the conductive circuit pattern 11b3. Thus, the extension of the crack in the −Z direction is delayed. Therefore, fracture of the second connection terminal 23b is delayed, and deterioration of the fatigue life of the second connection terminal 23b is prevented. As a result, the long-term reliability of the semiconductor device 1 according to the first embodiment is improved.

### Second Embodiment

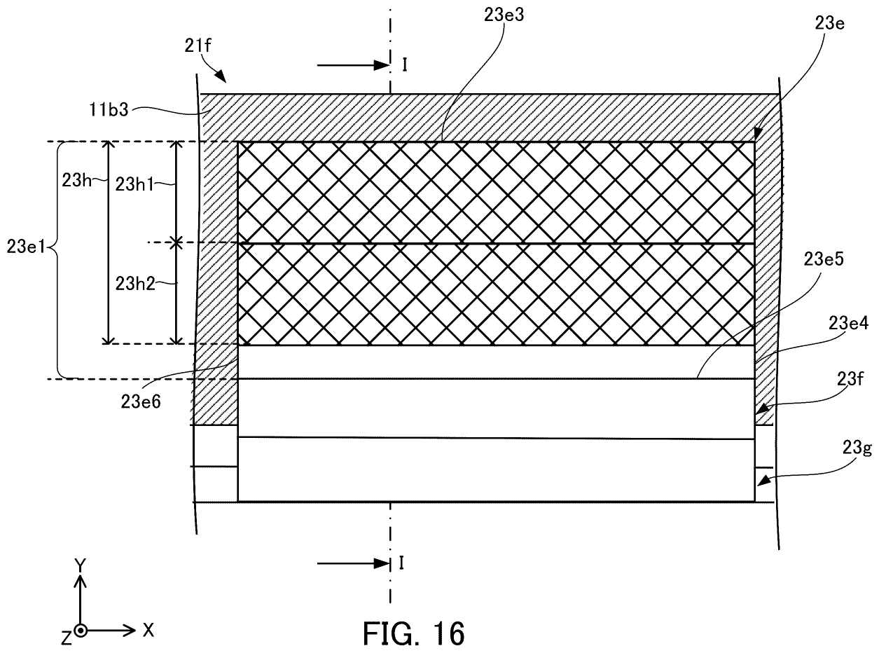

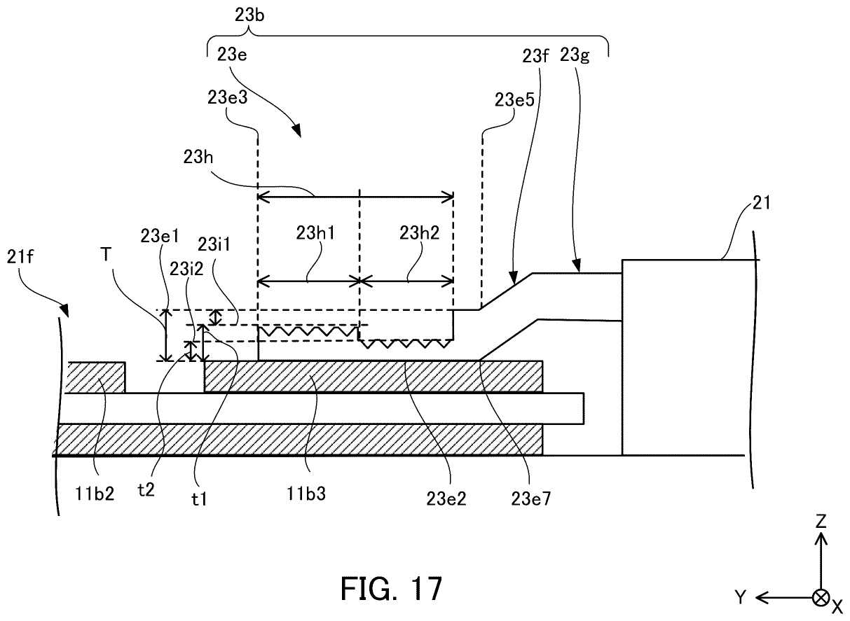

A second embodiment, which is different from the first embodiment, will be described with reference to FIGS. 16 and 17. According to the second embodiment, a second connection terminal 23b has an indentation area 23h in which a first sub-indentation area is formed closer to a bonding front end portion 23e3 than a second sub-indentation area is. FIG. 16 is a plan view of a connection terminal bonded to a conductive circuit pattern included in a semiconductor device according to a second embodiment. FIG. 17 is a sectional view of the connection terminal bonded to the conductive circuit pattern included in the semiconductor device according to the second embodiment. Specifically, FIG. 17 is a sectional view, taken along a dashed-dotted line I-I in FIG. 16. FIGS. 16 and 17 correspond to FIGS. 5 and 6, respectively.

The semiconductor device according to the second embodiment may also be manufactured in accordance with the flowchart in FIG. 7. However, the additional bonding step in step S3b in FIG. 7 according to the second embodiment differs from the additional bonding step according to the first embodiment.

According to the second embodiment, in the additional bonding step in step S3b performed after the bonding step in step S3a, first, a pressing tip portion 50 of a bonding tool 4 is changed. After the indentation area 23h is formed in step S3a by pressing a second bonding portion 23e until the thickness from a bottom surface 23e2 to a first upper end 23i1 reaches a first thickness t1, the pressing tip portion 50 of the bonding tool 4 is replaced by another pressing tip portion 50, which is smaller than the indentation area 23h.

Because the pressing tip portion 50 of the bonding tool 4 used in the bonding step in step S3a is larger than a second sub-indentation area 23h2 to be formed next, even when an area of a top surface 23e1 of the second bonding portion 23e, the area being near a bonding rear end portion 23e5, is pressed, forming the second sub-indentation area 23h2 fails. Thus, the pressing tip portion 50 is replaced by another pressing tip portion 50 matching the second sub-indentation area 23h2.

This pressing tip portion 50 has a shape matching the shape of the second sub-indentation area 23h2 in plan view. That is, a pressing tip portion 50 having a predetermined ±Y direction length with respect to the ±Y direction length of the indentation area 23h is used. The ±X direction width of the pressing tip portion 50 may be equal to or greater than the ±X direction width of a first sub-indentation area 23h1. In the second embodiment, as an example, the ±Y direction length of the pressing tip portion 50 may be half the ±Y direction length of the indentation area 23h.

After the pressing tip portion 50 of the bonding tool 4 is replaced, this bonding tool 4 is used to perform additional ultrasonic bonding in step S3b in FIG. 7. The pressing tip portion 50 of the bonding tool 4 is set on the top surface 23e1 of the second bonding portion 23e. In this step, the pressing tip portion 50 of the bonding tool 4 covers half the indentation area 23h in the ±Y direction length from the bonding rear end portion 23e5 to the bonding front end portion 23e3 of the top surface 23e1 of the second bonding portion 23e. In addition, this covered area stretches between the bonding side portions 23e4 and 23e6 on the top surface 23e1 of the second bonding portion 23e. The remaining area in the indentation area 23h will be the first sub-indentation area 23h1.

In this state, the pressing tip portion 50 of the bonding tool 4 presses the second bonding portion 23e of the second connection terminal 23b until the thickness reaches a second thickness t2 from the bottom surface 23e2 to a second upper end 2312. As a result, as illustrated in FIG. 17, the second sub-indentation area 23h2 having the second thickness t2 less than the first thickness t1 is formed in an area of the indentation area 23h where the first sub-indentation area 23h1 is not formed. These first sub-indentation area 23h1 and second sub-indentation area 23h2 formed as described above may have the same depths as those according to the first embodiment. The height of the level difference between the first sub-indentation area 23h1 and the second sub-indentation area 23h2 may fall within the same range according to the first embodiment.

In this way, an area of the bottom surface 23e2 of the second bonding portion 23e of the second connection terminal 23b, the area corresponding to the indentation area 23h, is bonded to the conductive circuit pattern 11b3.

In addition, as described above, the bonding area of the bottom surface 23e2 of the second bonding portion 23e with respect to the conductive circuit pattern 11b3 depends on the depth made by the pressing performed by the ultrasonic bonding. Thus, the second bonding area corresponding to the second sub-indentation area 23h2 is larger than the first bonding area corresponding to the first sub-indentation area 23h1.

In addition, in the second embodiment, too, the first area of the first sub-indentation area 23h1 and the second area of the second sub-indentation area 23h2 may be equal to each other. Although the first area of the first sub-indentation area 23h1 and the second area of the second sub-indentation area 23h2 are formed to be equal to each other, these first and second areas may be the same as or different from each other, depending on the area of the pressing tip portion 50 of the bonding tool 4.

The second embodiment assumes that the plurality of sub-indentation areas are the first and second sub-indentation areas 23h1 and 23h2. In the case where a plurality of sub-indentation areas are formed in the indentation area 23h, after the above-described bonding step is performed in step S3a, the additional bonding step is performed repeatedly, in which the pressing tip portion 50 of the bonding tool 4 is replaced by another pressing tip portion 50 corresponding to a desired sub-indentation area, the bonding tool 4 is moved linearly, and then the pressing is performed. In this way, at least one sub-indentation area may be formed in a line in the direction extending from the bonding rear end portion 23e5 to the bonding front end portion 23e3. In this case, too, the areas of the plurality of sub-indentation areas may be equal to or different from each other, depending on the area of the newly used pressing tip portion 50 of the bonding tool 4. Each time the bonding tool 4 is replaced, the pressing may be performed such that different depths are obtained. That is, each of the plurality of sub-indentation areas may have a different thickness from the bottom surface 23e2.

In addition, as in the second embodiment, in the indentation area 23h on the top surface 23e1 of the second bonding portion 23e, the second sub-indentation area 23h2 having the second thickness t2 may be formed near the bonding rear end portion 23e5, and the first sub-indentation area 23h1 having the first thickness t1 may be formed near the bonding front end portion 23e3. This may particularly be applied to the second bonding portion 23e of which the ±Y direction length is shorter than the ±X direction width in plan view. This second bonding portion 23e does not have a sufficient bonding area in the ±Y direction with respect to the conductive circuit pattern 11b3. To solve this problem, by forming the second sub-indentation area 23h2 near the bonding rear end portion 23e5 of the top surface 23e1 of the second bonding portion 23e, it is possible to obtain a larger bondable area of the second bonding portion 23e in the ±X direction. The ±Y direction length of the second bonding portion 23e where the indentation area 23h is formed may be 60% or greater and is less than 100% of the ±X direction width (the length between the bonding side portions 23e4 and 23e6). If the ±Y direction length of the second bonding portion 23e is less than 60% of the ±X direction width, needed bonding strength is not obtained.

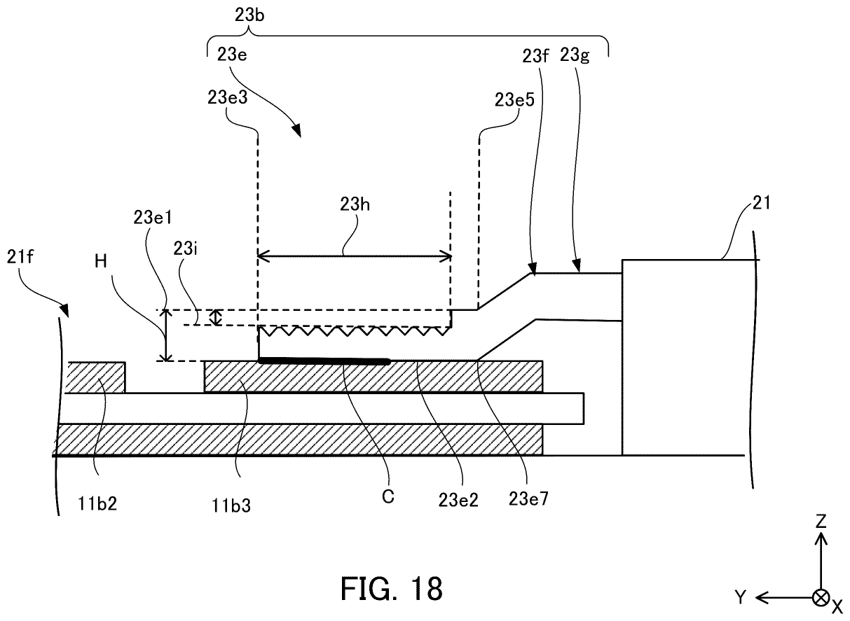

Hereinafter, a second connection terminal 23b included in a semiconductor device according to a reference example 2 will be described. FIG. 18 is a sectional view of a connection terminal bonded to a conductive circuit pattern included in a semiconductor device according to a reference example 2. The plan view of the connection terminal in FIG. 18 is the same as FIG. 14. Specifically, FIG. 18 is a sectional view, taken along the dashed-dotted line I-I in FIG. 14. FIG. 18 corresponds to FIG. 15.

In the case of the semiconductor device according to the reference example 2, unlike the reference example 1, ultrasonic bonding for shallowly pressing a second bonding portion 23e is performed in the bonding step (step S3a). As a result, only an indentation area 23h without any level difference is formed. The other aspects of the semiconductor device and the manufacturing method thereof are the same as those according to the reference example 1.

According to the reference example 2, the indentation area 23h formed on an entire top surface 23e1 of the second bonding portion 23e has a thickness t from a bottom surface 23e2 to an upper end 23i. The thickness t of the indentation area 23h is less than a thickness T of the second bonding portion 23e and is greater than the thickness t according to the reference example 1. The thickness t of the indentation area 23h may be, for example, approximately the first thickness t1 according to the second embodiment.

That is, according to the reference example 2, the depth of the upper end 23i in the indentation area 23h is less than that according to the reference example 1. Thus, the bonding area of the bottom surface 23e2, the bonding area corresponding to the indentation area 23h of the second bonding portion 23e according to the reference example 2, with respect to the conductive circuit pattern 11b3 is considered to be less than that according to the reference example 1. Thus, when stress is applied to the second bonding portion 23e of the second connection terminal 23b, a crack C could be more likely to occur in a portion near the bonding front end portion 23e3 at the interface of the bottom surface 23e2 of the second bonding portion 23e and the conductive circuit pattern 11b3, compared with the reference example 1. If stress is continuously applied, as illustrated in FIG. 18, the crack C further extends in the interface direction of the second bonding portion 23e of the second connection terminal 23b and the conductive circuit pattern 11b3, that is, in the −Y direction. If the crack C further extends, the second bonding portion 23e is detached from the conductive circuit pattern 11b3. Thus, in the case of the reference example 2, depending on the bonding area of the second bonding portion 23e of the second connection terminal 23b with respect to the conductive circuit pattern 11b3, the crack C could occur and extend. As a result, the fatigue life of the second connection terminal 23b deteriorates, and the long-term reliability of the semiconductor device deteriorates.

According to the reference example 2, too, as is the case with the reference example 1, a crack C could occur at the intersection of the −Y direction end portion of the indentation area 23h and the bottom surface 23e2. However, the thickness from the bottom surface 23e2 of the second bonding portion 23e in which the indentation area 23h according to the reference example 2 is formed is sufficiently greater than that according to the reference example 1. Thus, even if a crack C occurs at this intersection, the crack C is considered to extend more slowly in the thickness direction, compared with the reference example 1.

In the case of the semiconductor device 1 according to the second embodiment, the first thickness t1 of the first sub-indentation area 23h1 from the bottom surface 23e2 to the first upper end 23i1 is greater than the second thickness t2 of the second sub-indentation area 23h2 from the bottom surface 23e2 to the second upper end 2312. In addition, the first bonding area corresponding to the first sub-indentation area 23h1 is less than the second bonding area corresponding to the second sub-indentation area 23h2. Thus, even if a crack C occurs in a portion of the interface of the bottom surface 23e2 of the second bonding portion 23e and the conductive circuit pattern 11b3, the portion being near the bonding front end portion 23e3, the extension in the interface direction (−Y direction) of the second bonding portion 23e of the second connection terminal 23b and the conductive circuit pattern 11b3 is prevented. Thus, it is possible to delay detachment of the second bonding portion 23e of the second connection terminal 23b from the conductive circuit pattern 11b3. Thus, since detachment of the second connection terminal 23b is delayed, deterioration of the fatigue life of the second connection terminal 23b is prevented. As a result, the long-term reliability of the semiconductor device 1 according to the second embodiment is improved.

### Third Embodiment

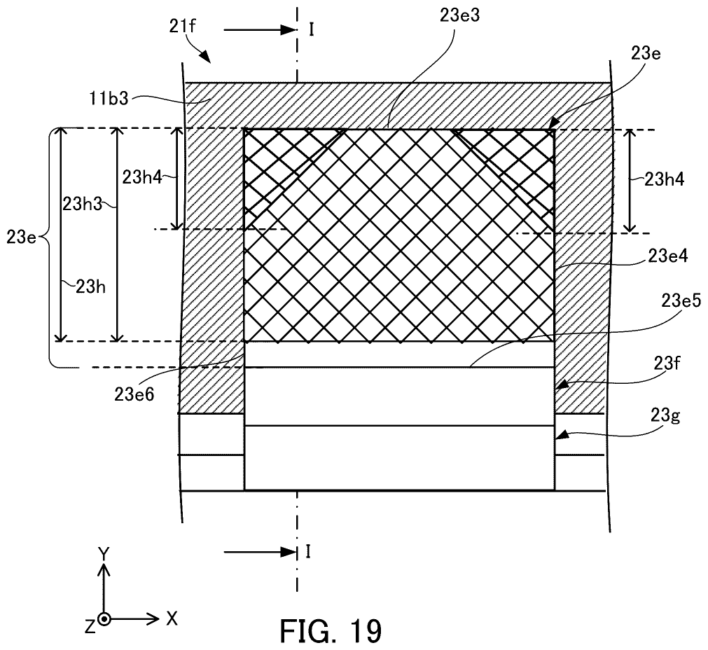

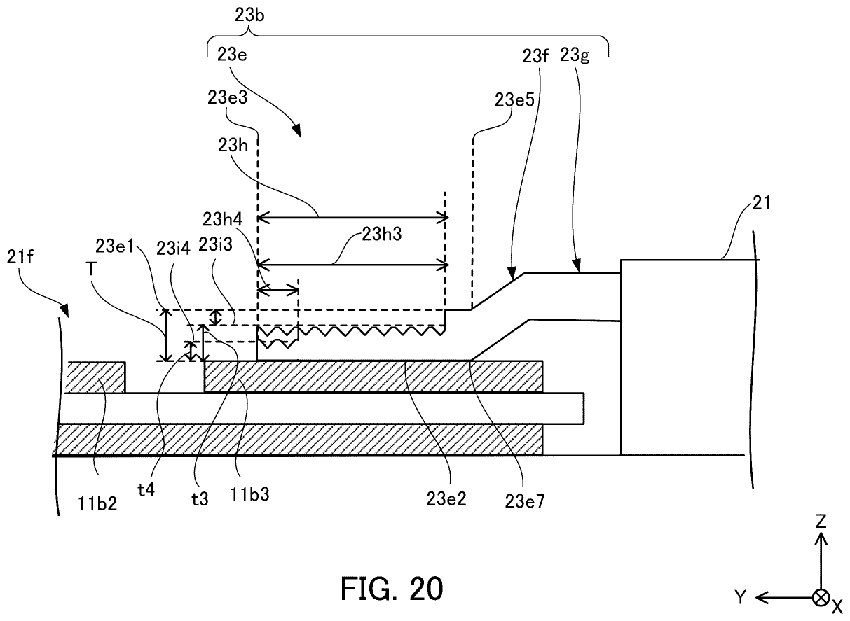

According to a third embodiment, a plurality of sub-indentation areas are formed in portions in an indentation area, the portions being different from those according to the first embodiment. For example, a case in which a plurality of sub-indentation areas are formed on two corner portions of an indentation area 23h formed on a top surface 23e1 of a second bonding portion 23e, the two corner portions being near a bonding front end portion 23e3, will be described with reference to FIGS. 19 and 20. FIG. 19 is a plan view of a connection terminal bonded to a conductive circuit pattern included in a semiconductor device according to a third embodiment. FIG. 20 is a sectional view of the connection terminal bonded to the conductive circuit pattern included in the semiconductor device according to the third embodiment. Specifically, FIG. 20 is a sectional view, taken along a dashed-dotted line I-I in FIG. 19. FIGS. 19 and 20 correspond to FIGS. 5 and 6, respectively.

The semiconductor device according to the third embodiment may also be manufactured in accordance with the flowchart in FIG. 7. However, the third embodiment differs from the first embodiment in the areas pressed in the additional bonding step in step S3b in FIG. 7. The other aspects of the semiconductor device and the manufacturing method thereof are the same as those of the semiconductor device 1 and the manufacturing method thereof according to the first embodiment.

In the bonding step in step S3a according to the third embodiment, too, as is the case with the first embodiment, a pressing tip portion 50 of a bonding tool 4 presses the second bonding portion 23e until the thickness from a bottom surface 23e2 to a third upper end 2313 reaches a third thickness t3, so as to form the indentation area 23h.

Next, in the additional bonding step in step S3b, the bonding tool 4 is separated from the second bonding portion 23e in the +Z direction, is moved to one corner portion of the indentation area 23h, the one corner portion being near the bonding front end portion 23e3, and the one corner portion is pressed in the same way as in the first embodiment, so as to form a fourth sub-indentation area 23h4. Next, the bonding tool 4 is separated from the second bonding portion 23e in the +Z direction, is moved to the other corner portion of the indentation area 23h, the other corner portion being near the bonding front end portion 23e3, and the other corner portion is pressed in the same way as in the first embodiment, so as to form another fourth sub-indentation area 23h4. The one corner portion and the other corner portion are deeply pressed by the pressing tip portion 50 of the bonding tool 4 such that the thickness of the second bonding portion 23e from the bottom surface 23e2 to a fourth upper end 2314 reaches a fourth thickness t4 less than the third thickness t3. In the indentation area 23h of the second bonding portion 23e, the area other than the two fourth sub-indentation areas 23h4 is a third sub-indentation area 23h3.

A fourth depth of the fourth sub-indentation areas 23h4 from the top surface 23e1 to the fourth upper end 2314 is greater than a third depth of the third sub-indentation area 23h3 from the top surface 23e1 to the third upper end 2313. The fourth depth of the fourth sub-indentation areas 23h4 and the third depth of the third sub-indentation area 23h3 correspond to the second depth of the second sub-indentation area 23h2 and the first depth of the first sub-indentation area 23h1 according to the first embodiment, and may be, for example, approximately 700 μm and 300 μm, respectively. In addition, there is a difference in level between the third sub-indentation area 23h3 and the fourth sub-indentation areas 23h4, as is the case with the first sub-indentation area 23h1 and the second sub-indentation area 23h2 according to the first embodiment. The difference in level may be, for example, between 0.1 mm and 0.4 mm, inclusive.

The individual fourth sub-indentation area 23h4 may be rectangular or triangular in plan view. According to the third embodiment, as illustrated in FIG. 19, the individual fourth sub-indentation area 23h4 is triangular in plan view. In this case, when the additional bonding step in step S3b is performed, the pressing tip portion 50 of the bonding tool 4, the pressing tip portion 50 being rectangular in plan view, is inclined with a predetermined angle and is pressed against one corner portion of the indentation area 23h, the one corner portion being near the bonding front end portion 23e3. When the other corner portion is pressed, too, the pressing tip portion 50 of the bonding tool 4, the pressing tip portion 50 being rectangular in plan view, is inclined with a predetermined angle in the opposite direction and is pressed against the other corner portion. It is preferable that the fourth sub-indentation areas 23h4 be formed to have a symmetrical shape and be formed at symmetrical locations at the one corner portion and the other corner portion. In addition, it is preferable that the fourth sub-indentation areas 23h4 be formed on two corner portions of the indentation area 23h formed on the top surface 23e1, the two corner portions being near the bonding front end portion 23e3. However, only one fourth sub-indentation area 23h4 may be formed on one of the corner portions.

In the case of a second connection terminal 23b according to the third embodiment, a third thickness t3 of the third sub-indentation area 23h3 included in the indentation area 23h with respect to a thickness T of the second bonding portion 23e from the bottom surface 23e2 to the top surface 23e1 is greater than the thickness t according to the reference example 1, for example. Thus, extension of a crack in the −Z direction is delayed. Thus, fracture of the second connection terminal 23b is delayed.

In addition, for example, according to the reference example 2, in plan view, stress is easily concentrated on the two corner portions on the bonding front end portion 23e3 of the second bonding portion 23e of the second connection terminal 23b, the second bonding portion 23e being bonded to the conductive circuit pattern 11b3. Thus, detachment easily occurs between the two corner portions of the bottom surface 23e2 of the second bonding portion 23e of the second connection terminal 23b and the conductive circuit pattern 11b3. According to the third embodiment, the fourth sub-indentation areas 23h4 are formed by deeply pressing the two corner portions of the top surface 23e1 of the second bonding portion 23e of the second connection terminal 23b, the two corner portions being near the bonding front end portion 23e3. Thus, the bonding strength of areas of the bottom surface 23e2 of the second bonding portion 23e of the second connection terminal 23b, the areas corresponding to the fourth sub-indentation areas 23h4, with respect to the conductive circuit pattern 11b3 are greater than that of the other area. Therefore, occurrence of detachment between the two corner portions of the bottom surface 23e2 of the second bonding portion 23e of the second connection terminal 23b and the conductive circuit pattern 11b3 is prevented. Thus, fracture and detachment of the second connection terminal 23b are delayed, and deterioration of the fatigue life of the second connection terminal 23b is prevented. As a result, the long-term reliability of the semiconductor device according to the third embodiment is improved.

### Fourth Embodiment

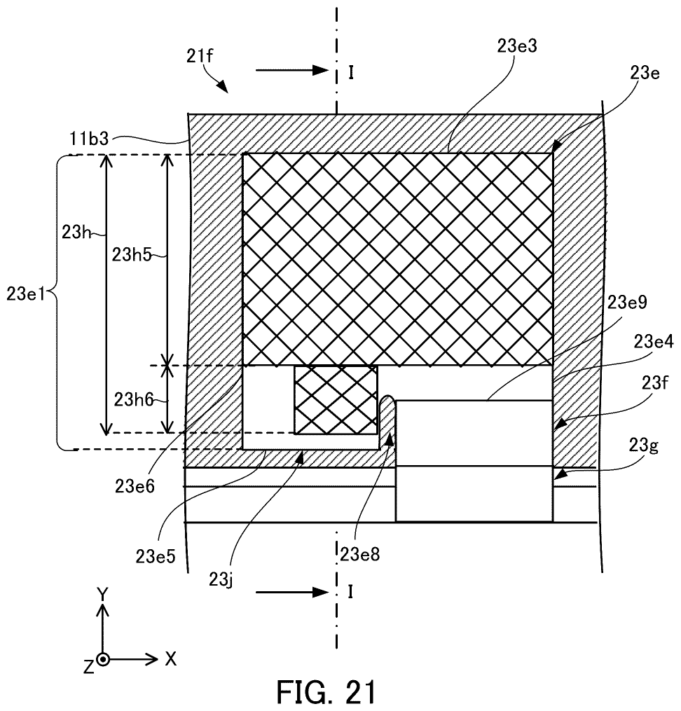

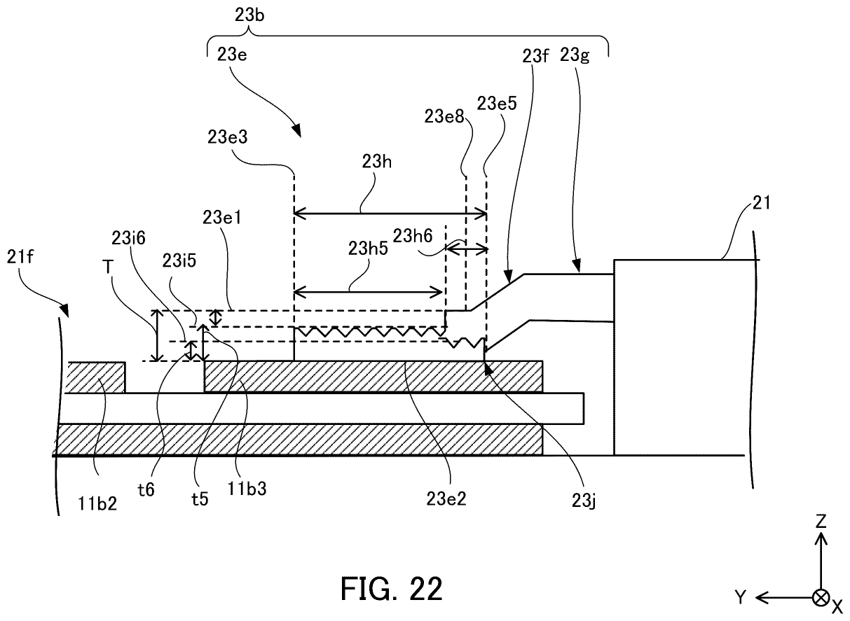

A fourth embodiment will be described with reference to FIGS. 21 and 22. According to the fourth embodiment, ultrasonic bonding is performed on a second connection terminal 23b having a shape different from that according to the first embodiment. FIG. 21 is a plan view of a connection terminal bonded to a conductive circuit pattern included in a semiconductor device according to a fourth embodiment. FIG. 22 is a sectional view of the connection terminal bonded to the conductive circuit pattern included in the semiconductor device according to the fourth embodiment. Specifically, FIG. 22 is a sectional view, taken along a dashed-dotted line I-I in FIG. 21. FIGS. 21 and 22 correspond to FIGS. 5 and 6, respectively.

A second bonding portion 23e according to the fourth embodiment includes a recess 23e8, which extends from a bonding rear end portion 23e5 toward a bonding front end portion 23e3 in plan view, at the bonding rear end portion 23e5. The second bonding portion 23e includes a projecting portion 23j, which projects in the −Y direction on the −X direction side of the recess 23e8 in plan view. The −Y direction end portion of the projecting portion 23j is the bonding rear end portion 23e5. Thus, in the case of the second bonding portion 23e, a bonding side portion 23e4 is shorter than a bonding side portion 23e6 by the length corresponding to the ±Y direction length of the recess 23e8. The ±X direction width of the projecting portion 23j and the ±X direction width of the recess 23e8 may be equal to each other.

In addition, a second ramp portion 23f is integrally connected to a recess bonding portion 23e9 of the recess 23e8, the recess bonding portion 23e9 being in the direction of the bonding front end portion 23e3. The second ramp portion 23f extends upward at a sharp angle from the recess bonding portion 23e9 to a second wiring portion 23g. Thus, according to the fourth embodiment, in plan view, the ±X direction width of the second ramp portion 23f may be approximately half the ±X direction width of the second bonding portion 23e, for example. The ±X direction width of a portion of the second wiring portion 23g, the portion being exposed to the outside from the outer frame 21, may be the same as the ±X direction width of the second ramp portion 23f.

The fourth embodiment will be descried by using the second connection terminal 23b as an example. The first connection terminals 22a, 22b, and 22c, the second connection terminals 23a and 23c, the W-phase output terminal 24a, the V-phase output terminal 24b, and the U-phase output terminal 24c may be formed in the same way as the second connection terminal 23b.

The semiconductor device according to the fourth embodiment may also be manufactured in accordance with the flowchart in FIG. 7. However, the following steps are performed in steps S3a and S3b. After step S2, ultrasonic bonding (bonding step) is performed on the second bonding portion 23e of the second connection terminal 23b, the second bonding portion 23e being disposed on a conductive circuit pattern 11b3 (step S3a in FIG. 7). First, a pressing tip portion 50 of a bonding tool 4 is set on a top surface 23e1 of the second bonding portion 23e. In this step, the pressing tip portion 50 of the bonding tool 4 covers an area of a predetermined length on the top surface 23e1 of the second bonding portion 23e from the bonding front end portion 23e3 toward the bonding rear end portion 23e5. The −Y direction end portion of the covered area is a little before the recess bonding portion 23e9. The covered area stretches between the bonding side portion 23e4 and the bonding side portion 23e6 on the top surface 23e1 of the second bonding portion 23e.

In this state, as is the case with the first embodiment, pressing is performed until the thickness from a bottom surface 23e2 to a fifth upper end 2315 reaches a fifth thickness t5. By this pressing, a fifth sub-indentation area 23h5 is formed on the top surface 23e1 of the second bonding portion 23e. In this way, an area on the bottom surface 23e2 of the second bonding portion 23e, the area corresponding to the fifth sub-indentation area 23h5, is bonded to the conductive circuit pattern 11b3.

Next, the additional bonding step in step S3b is performed. According to the fourth embodiment, the pressing tip portion 50 of the bonding tool 4 is replaced by another pressing tip portion to a 50 corresponding sixth sub-indentation area 23h6 to be formed. If the sixth sub-indentation area 23h6 is formed on the entire projecting portion 23j, part of the pressing tip portion 50 used in the bonding step in step S3a may be used, without replacing the pressing tip portion 50.

The pressing tip portion 50 of the bonding tool 4 after the replacement is set on the top surface 23e1 of the second bonding portion 23e. The pressing tip portion 50 of the bonding tool 4 covers an area of a predetermined length in the −Y direction on the top surface 23e1 of the second bonding portion 23e from an end portion of the fifth sub-indentation area 23h5, the end portion being near the bonding rear end portion 23e5, toward the bonding rear end portion 23e5. The covered area of the predetermined length may extend up to the bonding rear end portion 23e5 of the projecting portion 23j at its maximum. In addition, the covered area has a predetermined width from the ±X direction side portion of the projecting portion 23j of the second bonding portion 23e. The covered area this width may extend up to the bonding side portion 23e6 at its maximum. That is, the maximum area of the sixth sub-indentation area 23h6 is the projecting portion 23j.

In this state, as is the case with the first embodiment, the second bonding portion 23e of the second connection terminal 23b is pressed by the pressing tip portion 50 of the bonding tool 4 until a sixth thickness t6 from the bottom surface 23e2 to a sixth upper end 2316 is reached. In this way, as illustrated in FIG. 21, the sixth sub-indentation area 23h6 having the sixth thickness t6 less than the fifth thickness t5 is formed in an area including the projecting portion 23j adjacent to the fifth sub-indentation area 23h5.

A fifth depth of the fifth sub-indentation area 23h5 from the top surface 23e1 to the fifth upper end 2315 is less than a sixth depth of the sixth sub-indentation area 23h6 from the top surface 23e1 to the sixth upper end 2316. The fifth depth of the fifth sub-indentation area 23h5 and the sixth depth of the sixth sub-indentation area 23h6 correspond to the first depth of the first sub-indentation area 23h1 and the second depth of the second sub-indentation area 23h2 according to the first embodiment, and may be, for example, approximately 300 μm and 700 μm, respectively. In addition, there is a difference in level between the fifth sub-indentation area 23h5 and the sixth sub-indentation area 23h6, as is the case with the difference in level between the first and second sub-indentation areas 23h1 and 23h2 according to the first embodiment. The difference in level may be, for example, between 0.1 mm and 0.4 mm, inclusive. In this way, the indentation area 23h formed by the fifth sub-indentation area 23h5 and the sixth sub-indentation area 23h6 is formed.

In addition, according to the fourth embodiment, the second bonding portion 23e of the second connection terminal 23b includes the projecting portion 23j on the left side and the recess 23e8 on the right side in plan view in FIG. 21. Alternatively, the projecting portion 23j may be disposed on the right side, and the recess 23e8 may be disposed on the left side. In addition, the ±X direction width of the projecting portion 23j and the ±X direction width of the recess 23e8 may be different from each other.

In the case of the second connection terminal 23b according to the fourth embodiment, as is the case with the first embodiment, the fifth thickness t5 of the fifth sub-indentation area 23h5 included in the indentation area 23h is greater than the reference example 1, for example. Thus, extension of a crack in the ±Z direction is delayed. Therefore, fracture of the second connection terminal 23b is delayed.

In addition, stress is easily applied to the projecting portion 23j located at a side portion of the second ramp portion 23f of the second connection terminal 23b. In this case, the bottom surface 23e2 corresponding to the projecting portion 23j of the second bonding portion 23e could be detached from the conductive circuit pattern 11b3. In particular, it is conceivable that stress is easily applied to a corner portion of the projecting portion 23j of the second bonding portion 23e, the corner portion being near the recess 23e8, and to a connection point of the projecting portion 23j and the recess 23e8. According to the fourth embodiment, the sixth sub-indentation area 23h6 is formed by deeply pressing the projecting portion 23j of the top surface 23e1 of the second bonding portion 23e of the second connection terminal 23b. It is preferable that the sixth sub-indentation area 23h6 be formed in an area of the projecting portion 23j of the second bonding portion 23e, the area including the corner portion of the projecting portion 23j near the recess 23e8 and the connection point of the projecting portion 23j and the recess 23e8. Thus, the bonding strength of an area of the bottom surface 23e2 of the second bonding portion 23e of the second connection terminal 23b, the area corresponding to the sixth sub-indentation area 23h6, with respect to the conductive circuit pattern 11b3 is greater than the other area. Thus, occurrence of detachment of the projecting portion 23j of the bottom surface 23e2 of the second bonding portion 23e of the second connection terminal 23b from the conductive circuit pattern 11b3 is prevented. Therefore, fracture and detachment of the second connection terminal 23b are delayed, and deterioration of the fatigue life of the second connection terminal 23b is prevented. As a result, the long-term reliability of the semiconductor device according to the fourth embodiment is improved.

### Fifth Embodiment

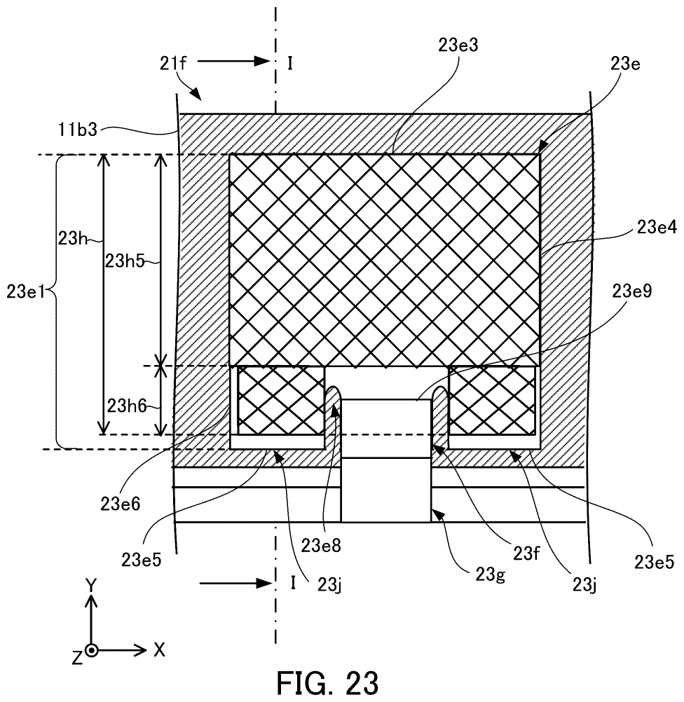

In a fifth embodiment, a modification of the second connection terminal 23b according to the fourth embodiment will be described with reference to FIG. 23. FIG. 23 is a plan view of a connection terminal bonded to a conductive circuit pattern included in a semiconductor device according to a fifth embodiment. The sectional view of the connection terminal, taken along a dashed-dotted line I-I in FIG. 23, is the same as FIG. 22. FIG. 23 corresponds to FIG. 5.

A second bonding portion 23e according to the fifth embodiment differs from the second bonding portion 23e according to the fourth embodiment in that a recess 23e8 extends from a bonding rear end portion 23e5 toward a bonding front end portion 23e3 in a center portion of the bonding rear end portion 23e5 in plan view. Thus, the second bonding portion 23e includes a projecting portion 23j extending in the −Y direction on either side of the recess 23e8 in the ±X directions in plan view. The −Y direction end portions of the projecting portions 23j are located at the bonding rear end portion 23e5 and are on the same plane. The ±X direction widths of the two projecting portions 23j and the recess 23e8 may be equal to each other.

In addition, as in the fourth embodiment, a second ramp portion 23f is integrally connected to a recess bonding portion 23e9 of the recess 23e8, the recess bonding portion 23e9 being near the bonding front end portion 23e3, and extends upward at a sharp angle from the recess bonding portion 23e9 to a second wiring portion 23g. In the fifth embodiment, in plan view, the ±X direction width of the second ramp portion 23f may be, for example, approximately one third of the ±X direction width of the second bonding portion 23e. The ±X direction width of a portion of the second wiring portion 23g, the portion being exposed to the outside from the outer frame 21, may be the same as the ±X direction width of the second ramp portion 23f.

The semiconductor device according to the fifth embodiment may also be manufactured in accordance with the flowchart in FIG. 7. However, the following steps are performed in steps S3a and S3b. After step S2, as is the case with the fourth embodiment, ultrasonic bonding (bonding step) is performed on the second bonding portion 23e of a second connection terminal 23b, the second bonding portion 23e being disposed on a conductive circuit pattern 11b3 (step S3a in FIG. 7). As a result, an area of a bottom surface 23e2 of the second bonding portion 23e, the area corresponding to a fifth sub-indentation area 23h5, is bonded to the conductive circuit pattern 11b3.

Next, the additional bonding step in step S3b is performed. According to the fifth embodiment, the additional bonding step is performed in the same way as that according to the fourth embodiment on each of the two projecting portions 23j located on both sides of the recess 23e8. In this way, as illustrated in FIG. 23, sixth sub-indentation areas 23h6, each of which has the sixth thickness t6 less than the fifth thickness t5, are formed at the two locations in areas adjacent to the fifth sub-indentation area 23h5 and including the projecting portions 23j.

In this way, an area of the bottom surface 23e2 of the second bonding portion 23e of the second connection terminal 23b, the area corresponding to an indentation area 23h, is bonded to the conductive circuit pattern 11b3. The fifth sub-indentation area 23h5 and the sixth sub-indentation areas 23h6 formed as described above may have the same depths as those according to the fourth embodiment. In addition, the level difference between the fifth sub-indentation area 23h5 and the sixth sub-indentation areas 23h6 may also fall within the same range as that according to the fourth embodiment.

In this way, the indentation area 23h formed by the fifth sub-indentation area 23h5 and the sixth sub-indentation areas 23h6 is formed. The projecting portions 23j located on the two sides and the recess 23e8 may have different ±X direction widths.

As is the case with the fourth embodiment, the second connection terminal 23b according to the fifth embodiment delays extension of a crack in the ±Z direction. Therefore, fracture of the second connection terminal 23b is delayed.

In addition, the deeply pressed sixth sub-indentation areas 23h6 are formed in the projecting portions 23j of the second bonding portion 23e. Thus, as is the case with the fourth embodiment, occurrence of detachment of the projecting portions 23j of the bottom surface 23e2 of the second bonding portion 23e of the second connection terminal 23b from the conductive circuit pattern 11b3 is prevented. Therefore, fracture and detachment of the second connection terminal 23b are delayed, and deterioration of the fatigue life of the second connection terminal 23b is prevented. As a result, the long-term reliability of the semiconductor device according to the fifth embodiment is improved.

The technique disclosed herein prevents deterioration of the fatigue life of terminals.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a conductive plate; and
a terminal including
a bonding portion having a rectangular plate shape in a plan view of the semiconductor device and having a bottom surface bonded to the conductive plate and a top surface having an indentation area with indentations, the bonding portion having a rear end and a front end opposite to each other, and
a ramp portion integrally connected to the bonding portion at the rear end thereof and extending from the bonding portion upward in a direction away from the top surface,
wherein the indentation area includes a plurality of sub-indentation areas, each having a thickness, from the bottom surface in a thickness direction orthogonal to the bottom surface, that is less than a thickness of the bonding portion from the bottom surface to the top surface at an area of the bonding portion other than the indentation area.

2. The semiconductor device according to claim 1, wherein the plurality of sub-indentation areas are aligned in a direction extending from the rear end to the front end of the bonding portion.

3. The semiconductor device according to claim 2, wherein in the indentation area, the plurality of sub-indentation areas include one sub-indentation area adjacent to the rear end and another sub-indentation area adjacent to the front end.

4. The semiconductor device according to claim 3, wherein in the thickness direction, a thickness of the bonding portion in the one sub-indentation area is greater than a thickness of the bonding portion in the another sub-indentation area.

5. The semiconductor device according to claim 4, wherein in the plan view, an area size of the one sub-indentation area is larger than an area size of the another sub-indentation area.

6. The semiconductor device according to claim 3, wherein in the thickness direction, a thickness of the bonding portion in the one sub-indentation area is less than a thickness of the bonding portion in the another sub-indentation area.

7. The semiconductor device according to claim 6, wherein a length of the bonding portion in a first direction from the rear end to the front end has a range of 60% to 100% of a length of the bonding portion in a second direction orthogonal to the first direction.

8. The semiconductor device according to claim 6, wherein in the plan view, an area size of the one sub-indentation area is smaller than an area size of the another sub-indentation area.

9. The semiconductor device according to claim 3, wherein in the plan view, an area size of the one sub-indentation area and an area size of the another sub-indentation area are equal to each other.

10. The semiconductor device according to claim 3, wherein in the thickness direction, a thickness of the bonding portion in the one sub-indentation area is greater than a thickness of the bonding portion in the another sub-indentation area by in a range of 0.1 mm to 0.4 mm.

11. The semiconductor device according to claim 1, wherein the plurality of sub-indentation areas are two sub-indentation areas each located at one of two corner portions respectively closer to the front end than to the rear end in the indentation area, and another sub-indentation area located in an area other than the two sub-indentation areas in the indentation area in the plan view.

12. The semiconductor device according to claim 11, wherein in the thickness direction, a thickness of the bonding portion in each of the two sub-indentation areas is less than a thickness of the bonding portion in the another sub-indentation area.

13. The semiconductor device according to claim 1,
wherein the bonding portion further includes a recess at the rear end recessed from the rear end toward the front end in the plan view,
wherein the ramp portion is integrally connected to the bonding portion at one end of the recess that is opposite to another end of the recess located at the rear end of the bonding portion, and
wherein the plurality of sub-indentation areas includes one sub-indentation area adjacent to the recess at the rear end and extends along the recess.

14. The semiconductor device according to claim 13, wherein in the thickness direction, a thickness of the bonding portion in the one sub-indentation area is less than a thickness of the bonding portion in regions of the plurality of sub-indentation areas other than the one sub-indentation area.

15. The semiconductor device according to claim 13, wherein the recess is provided at one of two opposite sides of the rear end in a direction orthogonal to a direction from the front end to the rear end.

16. The semiconductor device according to claim 13,
wherein the recess is provided in a center of the rear end in a direction orthogonal to a direction from the front end to the rear end, and
wherein the one sub-indentation area is located at at least one of two opposite sides of the recess at the rear end.

17. A semiconductor device manufacturing method, comprising:
preparing a conductive plate, and a terminal that includes a bonding portion having a rectangular flat plate shape and a ramp portion integrally connected to a rear end of the bonding portion and extending from the bonding portion upward in a direction away from a top surface of the bonding portion;
bonding a bottom surface of the bonding portion to the conductive plate by disposing the bottom surface of the bonding portion on the conductive plate, pressing the top surface of the bonding portion, thereby performing a bonding process that forms indentations in a primary area within the top surface; and
bonding the bottom surface of the bonding portion to the conductive plate by pressing a part of the primary area, thereby performing an additional bonding process that includes forming further indentations in a sub-area within the primary area, a thickness of the bonding portion in the sub-area being less than a thickness of the bonding portion in a region of the primary area other than the sub-area in a thickness direction orthogonal to the bottom surface.

18. The semiconductor device manufacturing method according to claim 17,
wherein the bonding process includes pressing the top surface of the bonding portion with a pressing surface of a bonding tool, and
wherein the additional bonding process includes forming a first sub-area within the primary area adjacent to the rear end by not performing the additional bonding process therein, pressing the top surface by moving the pressing surface linearly from the rear end toward a front end of the bonding portion opposite to the rear end, thereby forming one or more second sub-areas within the primary area that are aligned with the first sub-area in a direction from the rear end toward the front end.

19. The semiconductor device manufacturing method according to claim 17,
wherein the bonding process includes pressing the top surface of the bonding portion with a first pressing surface of the bonding tool, and
wherein the additional bonding process includes forming a first sub-area within the primary area adjacent to a front end of the bonding portion opposite to the rear end in the primary area by not performing the additional bonding process therein, and forming a second sub-area adjacent to the rear end by pressing the top surface in the second sub-area by a second pressing surface of the bonding tool, a length of the second pressing surface in a direction from the rear end toward the front end being less than a length of the first pressing surface.

20. A semiconductor device manufacturing method, comprising:
preparing a conductive plate and a terminal which includes a bonding portion that has a rectangular flat plate shape and a ramp portion that is integrally connected to a rear end of the bonding portion and that extends from the rear end upward in a direction away from a top surface of the bonding portion;
bonding a bottom surface of the bonding portion to the conductive plate by disposing the bottom surface of the bonding portion on the conductive plate, and pressing the top surface of the bonding portion to form a first sub-indentation area having a first thickness from the bottom surface; and
bonding the bottom surface of the bonding portion to the conductive plate by further forming at least one second sub-indentation area adjacent to the first sub-indentation area, having a second thickness from the bottom surface less than the first thickness, thereby forming an indentation area formed by the first sub-indentation area and the at least one second sub-indentation area.
